(19) United States
(12) Patent Application Publication
(10) Pub. No.: US 2025/0014992 A1
(43) Pub. Date: Jan. 9, 2025

(54) ELECTRONIC COMPONENT AND METHOD FOR MANUFACTURING THE SAME

(71) Applicant: ROHM CO., LTD., Kyoto-shi (JP)

(72) Inventor: Kazumasa NISHIO, Kyoto-shi (JP)

(73) Assignee: ROHM CO., LTD., Kyoto-shi (JP)

(21) Appl. No.: 18/897,269

(22) Filed: Sep. 26, 2024

Related U.S. Application Data
(63) Continuation of application No. PCT/JP2023/007288, filed on Feb. 28, 2023.

(30) Foreign Application Priority Data
Mar. 28, 2022 (JP) 2022-052630

(51) Int. Cl. H01L 23/522; H01L 21/768; H01L 23/528

(52) U.S. Cl. CPC H01L 23/5228; H01L 21/76801; H01L 23/5286; H01L 28/24

(57) ABSTRACT

An electronic component includes a semiconductor layer that has a first principal surface and a second principal surface at an opposite thereto, a lower insulating layer that is formed on the first principal surface of the semiconductor layer, a resistance layer that is formed on the lower insulating layer and has a notched portion extending in a predetermined first direction from a portion of a peripheral edge thereof, an upper insulating layer that is formed on the lower insulating layer such as to cover the resistance layer, and an uneven structure that is formed in a predetermined region of the first principal surface of the semiconductor layer including at least a region directly below the resistance layer and the uneven structure includes a plurality of grooves disposed at equal intervals in a second direction that is a direction along the first principal surface and is orthogonal to the first direction and extend in parallel to the first direction and a projection portion that is a portion between two adjacent grooves.

### CROSS-REFERENCE TO RELATED APPLICATIONS

The present application is a continuation application of PCT Application No. PCT/JP2023/007288, filed on Feb. 28, 2023, which corresponds to Japanese Patent Application No. 2022-052630 filed on Mar. 28, 2022, with the Japan Patent Office, and the entire disclosure of these applications is incorporated herein by reference.

### TECHNICAL FIELD

The present disclosure relates to an electronic component and a method for manufacturing the same.

### BACKGROUND ART

Japanese Patent Application Publication No. 2015-012259 discloses a semiconductor device that includes a silicon substrate, an insulating layer that is formed on the silicon substrate, a polysilicon resistor element that is formed on the insulating layer, and a wiring that is connected to the polysilicon resistor element on the polysilicon resistor element.

### BRIEF DESCRIPTION OF DRAWINGS

FIG. 1 is a schematic plan view showing an electronic component according to a preferred embodiment of the present invention and is a plan view showing a configuration in which a resistance layer is incorporated.

FIG. 2 is a sectional view taken along line II-II shown in FIG. 1.

FIG. 3 is an enlarged view of a region III of FIG. 2.

FIG. 4 is an enlarged plan view for describing a planar shape of the resistance layer.

FIG. 5 is an enlarged plan view showing a portion of a first principal surface of a semiconductor layer.

FIG. 6A is a sectional view showing a portion of a manufacturing process of the electronic component shown in FIG. 1 and is a sectional view corresponding to FIG. 2.

FIG. 6B is a sectional view showing a step subsequent to that of FIG. 6A.

FIG. 6C is a sectional view showing a step subsequent to that of FIG. 6B.

FIG. 6D is a sectional view showing a step subsequent to that of FIG. 6C.

FIG. 6E is a sectional view showing a step subsequent to that of FIG. 6D.

FIG. 6F is a sectional view showing a step subsequent to that of FIG. 6E.

FIG. 6G is a sectional view showing a step subsequent to that of FIG. 6F.

FIG. 6H is a sectional view showing a step subsequent to that of FIG. 6G.

FIG. 6I is a sectional view showing a step subsequent to that of FIG. 6H.

FIG. 6J is a sectional view showing a step subsequent to that of FIG. 6I.

FIG. 6K is a sectional view showing a step subsequent to that of FIG. 6J.

FIG. 6L is a sectional view showing a step subsequent to that of FIG. 6K.

FIG. 6M is a sectional view showing a step subsequent to that of FIG. 6L.

FIG. 6L is a sectional view showing a step subsequent to that of FIG. 6M.

FIG. 6O is a sectional view showing a step subsequent to that of FIG. 6N.

FIG. 6P is a sectional view showing a step subsequent to that of FIG. 6O.

FIG. 6O is a sectional view showing a step subsequent to that of FIG. 6P.

FIG. 6R is a sectional view showing a step subsequent to that of FIG. 6O.

FIG. 6S is a sectional view showing a step subsequent to that of FIG. 6R.

FIG. 7 is a plan view for describing an uneven structure of a first sample.

FIG. 8 is a plan view for describing an uneven structure of second to seventh samples.

FIG. 9 is a plan view for describing an uneven structure of eighth and ninth samples.

FIG. 10 is a plan view for describing an uneven structure of tenth and eleventh samples.

FIG. 11 is a plan view for describing an uneven structure of twelfth and thirteenth samples.

### DESCRIPTION OF EMBODIMENTS

A preferred embodiment of the present disclosure provides an electronic component including a semiconductor layer that has a first principal surface and a second principal surface at an opposite thereto, a lower insulating layer that is formed on the first principal surface of the semiconductor layer, a resistance layer that is formed on the lower insulating layer and has a notched portion extending in a predetermined first direction from a portion of a peripheral edge thereof, an upper insulating layer that is formed on the lower insulating layer such as to cover the resistance layer, and an uneven structure that is formed in a predetermined region of the first principal surface of the semiconductor layer including at least a region directly below the resistance layer, and where the uneven structure includes a plurality of grooves disposed at equal intervals in a second direction that is a direction along the first principal surface and is orthogonal to the first direction and extend in parallel to the first direction and a projection portion that is a portion between two adjacent grooves.

With this arrangement, an appropriate notched portion becomes easy to form in the resistance layer.

In the preferred embodiment of the present disclosure, the resistance layer, in plan view, is of a quadrilateral shape that has first opposing sides constituted of two sides parallel to the second direction and second opposing sides constituted of two sides parallel to the first direction and the notched portion extends from a length intermediate portion of one side among the first opposing sides toward the other side among the first opposing sides.

The preferred embodiment of the present disclosure includes a first via electrode that is embedded in the lower insulating layer and with which an upper end is connected to a portion of the resistance layer close to one side among the second opposing sides and a second via electrode that is embedded in the lower insulating layer and with which an upper end is connected to a portion of the resistance layer close to the other side among the second opposing sides.

The preferred embodiment of the present disclosure includes a first lower wiring layer that is formed in a region at the lower insulating layer side with respect to the resistance layer and is electrically connected to the first via electrode and a second lower wiring layer that is formed in a region at the lower insulating layer side with respect to the resistance layer and is electrically connected to the second via electrode.

In the preferred embodiment of the present disclosure, the first lower wiring layer extends outward from an inner side of the resistance layer with respect to the one side among the second opposing sides in plan view, the second lower wiring layer extends outward from the inner side of the resistance layer with respect to the other side among the second opposing sides in plan view, and the first lower wiring layer and the second lower wiring layer are disposed at an interval in the second direction in plan view.

In the preferred embodiment of the present disclosure, the resistance layer is connected in series to the first lower wiring layer and the second lower wiring layer.

The preferred embodiment of the present disclosure includes a first upper wiring layer that is formed on the upper insulating layer and is electrically connected to the first lower wiring layer and a second upper wiring layer that is formed on the upper insulating layer and is electrically connected to the second lower wiring layer.

In the preferred embodiment of the present disclosure, the resistance layer is connected in series to the first upper wiring layer and the second upper wiring layer.

The preferred embodiment of the present disclosure includes a first long via electrode that penetrates through the upper insulating layer and a portion of the lower insulating layer and is electrically connected to the first lower wiring layer and the first upper wiring layer and a second long via electrode that penetrates through the upper insulating layer and a portion of the lower insulating layer and is electrically connected to the second lower wiring layer and the second upper wiring layer.

In the preferred embodiment of the present disclosure, the resistance layer is positioned on a straight line joining the first long via electrode and the second long via electrode in plan view.

In the preferred embodiment of the present disclosure, the semiconductor layer includes a device region in which a functional device is formed and an outside region outside the device region and the resistance layer is formed in the outside region in plan view.

In the preferred embodiment of the present disclosure, the resistance layer is constituted of a metal thin film containing at least one among CrSi, CrSio, and CrSiN.

In the preferred embodiment of the present disclosure, a depth of the grooves is not less than 100 nm and not more than 300 nm and a width of the grooves and an interval of the grooves are not less than 0.2 μm and not more than 1 μm.

In the preferred embodiment of the present disclosure, the depth of the grooves is not less than 150 nm and not more than 300 nm and the width of the grooves and the interval of the grooves are not less than 0.2 μm and not more than 1 μm.

In the preferred embodiment of the present disclosure, the lower insulating layer includes a plurality of lower silicon oxide films that are laminated and the upper insulating layer includes an upper silicon oxide film that is formed on the lower insulating layer such as to cover the resistance layer.

A preferred embodiment of the present disclosure provides a method for manufacturing an electronic component including a step of forming an uneven structure in a predetermined region of a first principal surface of a semiconductor layer having the first principal surface and a second principal surface at an opposite thereto, a step of forming a lower insulating layer on the first principal surface of the semiconductor layer, a step of forming a resistance layer on the lower insulating layer, a step of forming an upper insulating layer on the lower insulating layer such as to cover the resistance layer, and a step of forming, in the resistance layer, a notched portion extending in a predetermined first direction from a portion of a peripheral edge of the resistance layer by irradiating a laser light onto the resistance layer via the upper insulating layer, and where the predetermined region is a region that includes at least a region of the first principal surface of the semiconductor layer directly below the resistance layer and, in the step of forming the uneven structure, the uneven structure is formed by forming, in the predetermined region, a plurality of grooves extending in parallel to the first direction at equal intervals in a second direction that is a direction along the first principal surface and is orthogonal to the first direction.

With this manufacturing method, an electronic component with which an appropriate notched portion becomes easy to form in the resistance layer can be manufactured.

Preferred embodiments of the present disclosure shall be described in detail below with reference to the attached drawings.

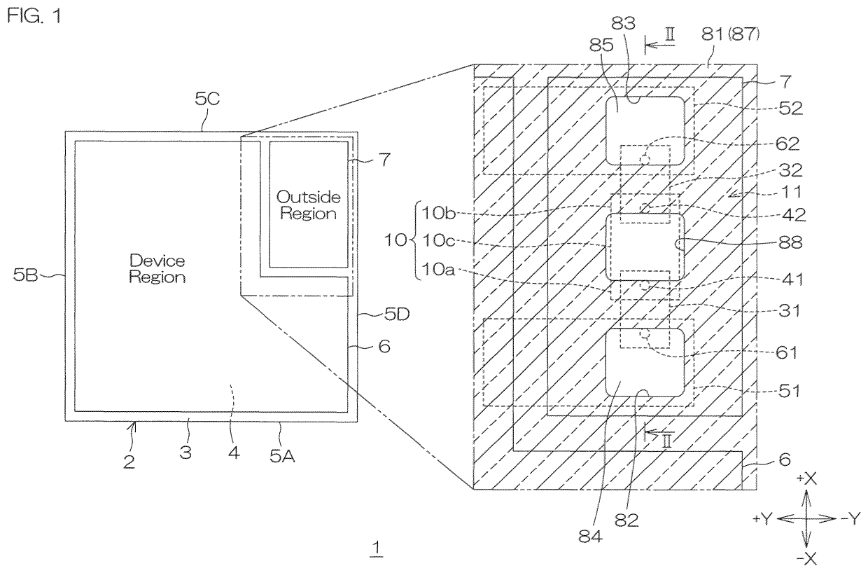

FIG. 1 is a schematic plan view showing an electronic component 1 according to a preferred embodiment of the present invention and is a plan view showing a configuration in which a resistance layer 10 is incorporated.

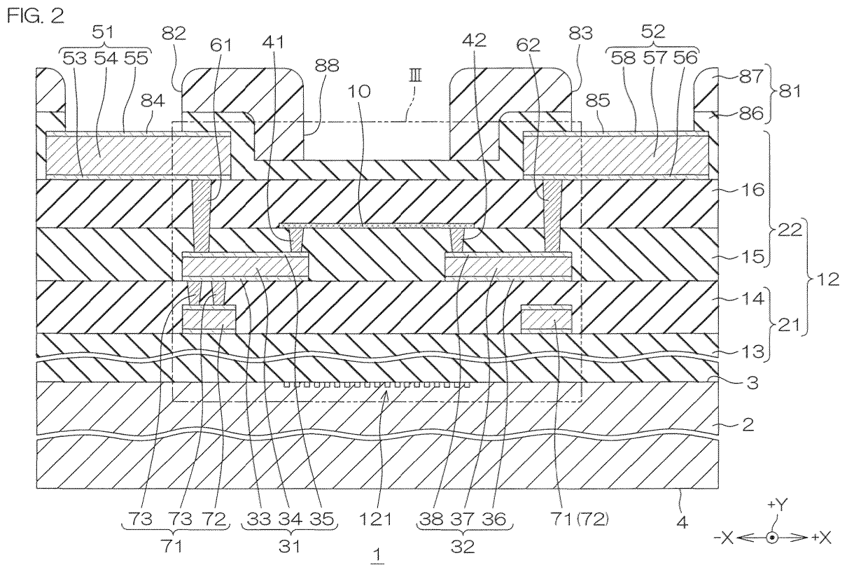

For convenience of description, a +X direction, a −X direction, a +Y direction, and a −Y direction shown in FIG. 1 and FIG. 2 are used at times in the following description. The +X direction is a predetermined direction along a front surface of a semiconductor layer 2 in plan view and the +Y direction is a direction along the front surface of the semiconductor layer 2 and is a direction that is orthogonal to the +X direction in plan view. The −X direction is a direction opposite to the +X direction and the −Y direction is a direction opposite to the +Y direction. The +X direction and the −X direction shall be referred to simply as the “X direction” when referred to collectively. The +Y direction and the −Y direction shall be referred to simply as the “Y direction” when referred to collectively.

The electronic component 1 is a semiconductor device that contains a conductor material or a semiconductor material or includes various functional devices formed using properties, etc., of a semiconductor material. The electronic component 1 includes a semiconductor layer 2 of chip shape formed in a rectangular parallelepiped shape. The semiconductor layer 2 includes a first principal surface 3 at one side, a second principal surface 4 at another side, and side surfaces 5A, 5B, 5C, and 5D connecting the first principal surface 3 and the second principal surface 4.

The first principal surface 3 is a device forming surface. The first principal surface 3 and the second principal surface 4 are formed in quadrilateral shapes (in this preferred embodiment, square shapes) in a plan view as viewed in a direction normal to the surfaces (hereinafter referred to simply as “plan view”).

The semiconductor layer 2 may be an Si semiconductor layer that contains Si (silicon) as an example of the semiconductor material. The Si semiconductor layer may have a laminated structure that includes an Si semiconductor substrate and an Si epitaxial layer. The Si semiconductor layer may have a single layer structure constituted of the Si semiconductor substrate. In this preferred embodiment, the semiconductor layer 2 is constituted of the Si semiconductor substrate.

The semiconductor layer 2 may be an SiC semiconductor layer that contains SiC (silicon carbide) as an example of the semiconductor material. The SiC semiconductor layer may have a laminated structure that includes an SiC semiconductor substrate and an SiC epitaxial layer. The SiC semiconductor layer may have a single layer structure constituted of the SiC semiconductor substrate.

The semiconductor layer 2 may be a compound semiconductor layer that contains a compound semiconductor material as an example of the semiconductor material. The compound semiconductor layer may have a laminated structure that includes a compound semiconductor substrate and a compound semiconductor epitaxial layer. The compound semiconductor layer may have a single layer structure constituted of the compound semiconductor substrate. The compound semiconductor material may be any of group III to V compound semiconductor materials. The semiconductor layer 2 may contain at least one among AlN (aluminum nitride), InN (indium nitride), GaN (gallium nitride), and GaAs (gallium arsenide) as examples of the group III to V compound semiconductor materials.

The semiconductor layer 2 includes a device region 6 and an outside region 7. The device region 6 is a region in which a functional device is formed. The device region 6 is formed in an inner region at intervals from the side surfaces 5A to 5D of the semiconductor layer 2. The device region 6 is formed in an L shape in plan view in this preferred embodiment. The planar shape of the device region 6 is arbitrary and is not restricted to the planar shape shown in FIG. 1.

The functional device is formed in the semiconductor layer 2. More specifically, the functional device is formed using the first principal surface 3 of the semiconductor layer 2 and/or a surface layer portion of the first principal surface 3. The functional device may include at least one among a passive device, a semiconductor rectifying device, and a semiconductor switching device. The passive device may include a semiconductor passive device.

The passive device (semiconductor passive device) may include at least one among a resistor, a capacitor, and a coil. The semiconductor rectifying device may include at least one among a pn junction diode, a Zener diode, a Schottky barrier diode, and a fast recovery diode.

The semiconductor switching device may include at least one among a BJT (bipolar junction transistor), a MISFET (metal insulator field effect transistor), an IGBT (insulated gate bipolar junction transistor), and a JFET (junction field effect transistor).

The functional device may include a circuit network selectively combining at least two among the passive device (semiconductor passive device), the semiconductor rectifying device, and the semiconductor switching device. The circuit network may form a portion or an entirety of an integrated circuit.

The integrated circuit may include an SSI (small scale integration), an LSI (large scale integration), an MSI (medium scale integration), a VLSI (very large scale integration), or an ULSI (ultra-very large scale integration).

The outside region 7 is a region outside the device region 6. The outside region 7 does not include a functional device. In this preferred embodiment, the outside region 7 is demarcated in a region between the side surfaces 5A to 5D of the semiconductor layer 2 and the device region 6. In this preferred embodiment, the outside region 7 is formed in a quadrilateral shape in plan view.

The planar shape of the outside region 7 is arbitrary and is not restricted to the planar shape shown in FIG. 1. A positioning and the planar shape of the outside region 7 are arbitrary and are not restricted to the positioning and the planar shape shown in FIG. 1. The outside region 7 may be formed at a central portion of the first principal surface 3 in plan view.

In the outside region 7, a resistance circuit 11, including the resistance layer 10 constituted of a metal thin film, is formed at an interval from the first principal surface 3 of the semiconductor layer 2. That is, in this preferred embodiment, the resistance circuit 11 (resistance layer 10) is formed to avoid the device region 6 in plan view. The resistance circuit 11 (resistance layer 10) is electrically connected to the functional device.

By disposing the resistance circuit 11 (resistance layer 10) in the outside region 7, an electrical influence that the resistance circuit 11 has on the device region 6 can be suppressed and an electrical influence that the device region 6 has on the resistance circuit 11 can be suppressed. For example, a parasitic capacitance between the device region 6 and the resistance circuit 11 can be suppressed. That is, reduction of noise and improvement of Q value can be achieved.

Although with this preferred embodiment, an example where the resistance circuit 11 includes the single resistance layer 10 shall be described, the resistance circuit 11 may include a plurality (two or more) of resistance layers 10 instead. In the following, the resistance layer 10 (resistance circuit 11) shall be described specifically with reference to FIG. 2 to FIG. 5 in addition to FIG. 1.

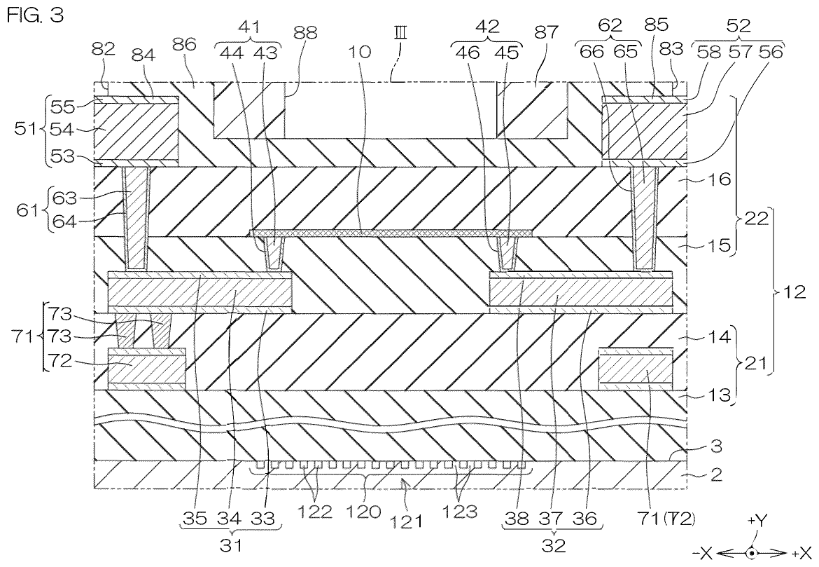

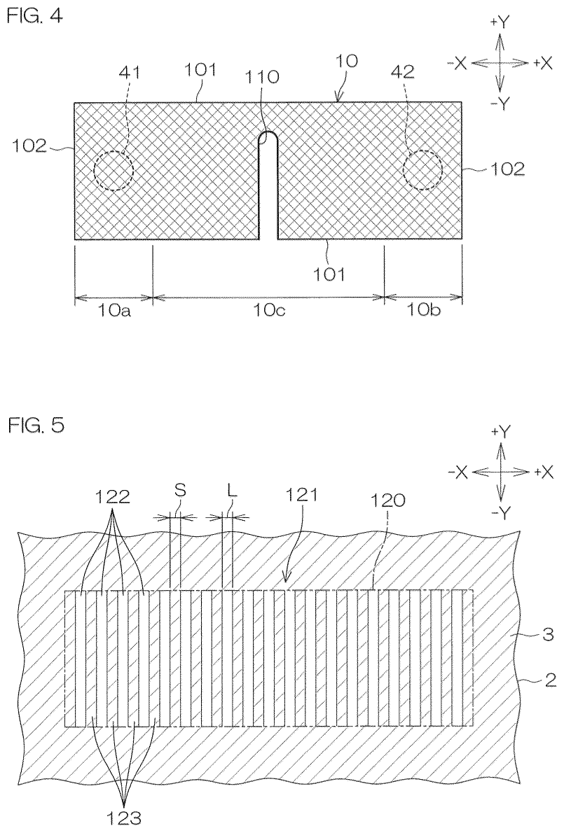

FIG. 2 is a sectional view taken along line II-II shown in FIG. 1. FIG. 3 is an enlarged view of a region III of FIG. 2. FIG. 4 is a plan view for describing a planar shape of the resistance layer 10. FIG. 5 is an enlarged plan view showing a portion of the first principal surface of the semiconductor layer.

In the device region 6 and the outside region 7, a multilayer wiring structure 12 is formed on the first principal surface 3 of the semiconductor layer 2. The multilayer wiring structure 12 has a laminated structure in which a plurality of insulating layers are laminated and includes a plurality of wiring layers selectively formed inside the plurality of insulating layers.

The multilayer wiring structure 12 includes, for example, a first insulating layer 13, a second insulating layer 14, a third insulating layer 15, and a fourth insulating layer 16 that are laminated in that order from the first principal surface 3 side of the semiconductor layer 2. The terms “first,” “second,” “third,” and “fourth” related to the first to fourth insulating layers 13 to 16 are provided to identify the insulating layers in the drawing and are not intended to assign an order.

The number of laminations of the insulating layers in the multilayer wiring structure 12 is arbitrary and is not restricted to the number of laminations shown in FIG. 2. The multilayer wiring structure 12 may thus include less than four insulating layers or may include five or more insulating layers.

The first to fourth insulating layers 13 to 16 respectively have principal surfaces. The principal surfaces of the first to fourth insulating layers 13 to 16 are respectively formed flatly. The principal surfaces of the first to fourth insulating layers 13 to 16 respectively extend parallel to the first principal surface 3 of the semiconductor layer 2. The principal surfaces of the first to fourth insulating layers 13 to 16 may respectively be ground surfaces. In this preferred embodiment, the fourth insulating layer 16 is an example of an “upper insulating layer” of the present disclosure. The insulating layers 13, 14, and 15 interposed between the semiconductor layer 2 and the fourth insulating layer 16 correspond to being a “lower insulating layer” of the present disclosure.

The first to fourth insulating layers 13 to 16 may each have a laminated structure that includes a silicon oxide film and a silicon nitride film. In this case, the silicon nitride film may be formed on the silicon oxide film or the silicon oxide film may be formed on the silicon nitride film.

The first to fourth insulating layers 13 to 16 may each have a single layer structure constituted of a silicon oxide film or a silicon nitride film. The first to fourth insulating layers 13 to 16 are preferably formed of an insulating material constituted of the same type of substance. In this preferred embodiment, the first to fourth insulating layers 13 to 16 each have a single layer structure constituted of a silicon oxide film.

Thicknesses of the first to fourth insulating layers 13 to 16 may each be not less than 100 nm and not more than 3500 nm. The thicknesses of the first to fourth insulating layers 13 to 16 may each be not less than 100 nm and not more than 500 nm, not less than 500 nm and not more than 1000 nm, not less than 1000 nm and not more than 1500 nm, not less than 1500 nm and not more than 2000 nm, not less than 2000 nm and not more than 2500 nm, not less than 2500 nm and not more than 3000 nm, or not less than 3000 nm and not more than 3500 nm. Preferably, the thicknesses of the first to fourth insulating layers 13 to 16 are each not less than 100 nm and not more than 1500 nm. The thicknesses of the first to fourth insulating layers 13 to 16 may be equal to each other or may differ from each other.

In this preferred embodiment, the multilayer wiring structure 12 includes a connection circuit forming layer 21 and a resistance circuit forming layer 22 that are formed in mutually different layers.

The connection circuit forming layer 21 is formed at the first principal surface 3 side of the semiconductor layer 2. The connection circuit forming layer 21 includes the first insulating layer 13 and the second insulating layer 14. The connection circuit forming layer 21 is a layer with one purpose being electrical connection of the device region 6 (functional device) and the outside region 7 (resistance circuit 11). A specific structure of the connection circuit forming layer 21 shall be described later.

The resistance circuit forming layer 22 is formed on the connection circuit forming layer 21. The resistance circuit forming layer 22 includes the third insulating layer 15 and the fourth insulating layer 16. The resistance circuit forming layer 22 is a layer with one purpose being forming of the resistance circuit 11 (resistance layer 10) in the outside region 7.

The resistance circuit 11 includes a first lower wiring layer 31, a second lower wiring layer 32, the resistance layer 10, a first via electrode 41, a second via electrode 42, a first upper wiring layer 51, a second upper wiring layer 52, a first long via electrode 61, and a second long via electrode 62.

The first lower wiring layer 31 and the second lower wiring layer 32 are disposed at an interval in the X direction on the connection circuit forming layer 21 (second insulating layer 14). The first lower wiring layer 31 and the second lower wiring layer 32 are covered by the third insulating layer 15.

In this preferred embodiment, the first lower wiring layer 31 has a laminated structure in which a plurality of electrode layers are laminated. The first lower wiring layer 31 includes a first barrier layer 33, a main body layer 34, and a second barrier layer 35 that are laminated in that order from above the connection circuit forming layer 21 (second insulating layer 14).

In this preferred embodiment, the first barrier layer 33 has a laminated structure including a Ti layer and a TiN layer that are laminated in that order from above the connection circuit forming layer 21 (second insulating layer 14). The first barrier layer 33 may instead have a single layer structure constituted of the Ti layer or the TiN layer.

The main body layer 34 has a resistance value less than a resistance value of the first barrier layer 33 and a resistance value of the second barrier layer 35. The main body layer 34 has a thickness exceeding a thickness of the first barrier layer 33 and a thickness of the second barrier layer 35. The main body layer 34 may contain at least one type of substance among Al, Cu, AlSiCu alloy, AlSi alloy, and AlCu alloy. In this preferred embodiment, the main body layer 34 has a single layer structure constituted of an AlCu alloy layer.

In this preferred embodiment, the second barrier layer 35 has a laminated structure that includes a Ti layer and a TiN layer that are laminated in that order from above the main body layer 34. The second barrier layer 35 may instead have a single layer structure constituted of the Ti layer or the TiN layer.

The second lower wiring layer 32 is disposed at the +X side with respect to the first lower wiring layer 31. In this preferred embodiment, the second lower wiring layer 32 has a laminated structure in which a plurality of electrode layers are laminated. The second lower wiring layer 32 includes a first barrier layer 36, a main body layer 37, and a second barrier layer 38 that are laminated in that order from above the connection circuit forming layer 21 (second insulating layer 14).

In this preferred embodiment, the first barrier layer 36 has a laminated structure including a Ti layer and a TiN layer that are laminated in that order from above the connection circuit forming layer 21 (second insulating layer 14). The first barrier layer 36 may instead have a single layer structure constituted of the Ti layer or the TiN layer.

The main body layer 37 has a resistance value less than a resistance value of the first barrier layer 36 and a resistance value of the second barrier layer 38. The main body layer 37 has a thickness exceeding a thickness of the first barrier layer 36 and a thickness of the second barrier layer 38. The main body layer 37 may contain at least one type of substance among Al, Cu, AlSiCu alloy, AlSi alloy, and AlCu alloy. In this preferred embodiment, the main body layer 37 has a single layer structure constituted of an AlCu alloy layer.

In this preferred embodiment, the second barrier layer 38 has a laminated structure that includes a Ti layer and a TiN layer that are laminated in that order from above the main body layer 37. The second barrier layer 38 may instead have a single layer structure constituted of the Ti layer or the TiN layer.

The resistance layer 10 is disposed on the third insulating layer 15. As shown in FIG. 4, the resistance layer 10, in plan view, is of a quadrilateral shape (rectangular shape) that is long in the X direction and has a pair of first opposing sides 101 that are parallel to the X direction and a pair of second opposing sides 102 that are parallel to the Y direction. In plan view, the resistance layer 10 is disposed such as to straddle the first lower wiring layer 31 and the second lower wiring layer 32.

The resistance layer 10 includes a first end portion 10a at the −X side, a second end portion 10b at the +X side, and a connection portion 10c connecting the first end portion 10a and the second end portion 10b. The first end portion 10a of the resistance layer 10 is disposed on a +X side end portion of a front surface of the first lower wiring layer 31. The second end portion 10b of the resistance layer 10 is disposed on a −X side end portion of a front surface of the second lower wiring layer 32.

The resistance layer 10 includes a single notched portion 110 formed in the connection portion 10c. The notched portion 110 extends in a direction (Y direction) intersecting a direction in which the connection portion 10c extends. In this preferred embodiment, the notched portion 110 extends in the Y direction from one side 101 to the other side 101 among the first opposing sides 101 of the resistance layer 10 that are parallel to the X direction. Also, in FIG. 1 to FIG. 3, the notched portion 110 is omitted.

The notched portion 110 is a laser light processing mark with which a partial region of the connection portion 10c has been fusion cut by a laser light irradiating. A current path of the resistance layer 10 is extended by the notched portion 110. A resistance value of the resistance layer 10 is thereby increased. The resistance value of the resistance layer 10 can be adjusted in an increasing direction by the notched portion 110.

The connection portion 10c extends in a band shape in a region between the first end portion 10a and the second end portion 10b. The connection portion 10c extends in the band shape along a straight line connecting the first end portion 10a and the second end portion 10b. In this preferred embodiment, the first end portion 10a, the second end portion 10b, and the connection portion 10c of the resistance layer 10 are formed with uniform width.

The resistance layer 10 is preferably constituted of a metal thin film containing at least one among CrSi (chromium silicon alloy), CrSiO (chromium silicon oxide alloy), and CrSiN (chromium silicon nitride alloy). The resistance layer 10 especially preferably contains CrSi. The resistance layer 10 may have a single layer structure constituted of a CrSi film, a CrSiO film, or a CrSiN film. In this preferred embodiment, the resistance layer 10 has a single layer structure constituted of the CrSi film.

The resistance layer 10 may be constituted of a metal thin film containing at least one among CrSi (chromium silicon alloy), TaN (tantalum nitride), and TiN (titanium nitride). The resistance layer 10 may have a single layer structure constituted of a TaN film or a TiN film.

The resistance layer 10 may have a laminated structure including a CrSi film and a TaN film laminated in any order. The resistance layer 10 may have a laminated structure including a CrSi film and a TiN film laminated in any order. The resistance layer 10 may have a laminated structure including a TaN film and a TiN film laminated in any order. The resistance layer 10 may have a laminated structure including a CrSi film, a TaN film, and a TiN film laminated in any order.

A thickness of the resistance layer 10 may be not less than 0.1 nm and not more than 100 nm. The thickness of the resistance layer 10 may be not less than 0.1 nm and not more than 10 nm, not less than 10 nm and not more than 20 nm, not less than 20 nm and not more than 30 nm, not less than 30 nm and not more than 40 nm, not less than 40 nm and not more than 50 nm, not less than 50 nm and not more than 60 nm, not less than 60 nm and not more than 70 nm, not less than 70 nm and not more than 80 nm, not less than 80 nm and not more than 90 nm, or not less than 90 nm and not more than 100 nm. The thickness of the resistance layer 10 is preferably not less than 1 nm and not more than 20 nm.

The resistance layer 10 is interposed in a region between the third insulating layer 15 and the fourth insulating layer 16. More specifically, the resistance layer 10 is formed as a film on the principal surface of the third insulating layer 15. On the principal surface of the third insulating layer 15, no film-shaped or layer-shaped wiring besides the resistance layer 10 is formed in the device region 6 and the outside region 7. The third insulating layer 15 is provided for forming the resistance layer 10.

By disposing the resistance layer 10 in the outside region 7, an electrical influence that the resistance layer 10 has on the device region 6 can be suppressed and an electrical influence that the device region 6 has on the resistance layer 10 can be suppressed. For example, a parasitic capacitance between the device region 6 and the resistance layer 10 can be suppressed. That is, reduction of noise and improvement of Q value can be achieved.

The first via electrode 41 is electrically connected to the resistance layer 10 and the first lower wiring layer 31. The second via electrode 42 is electrically connected to the resistance layer 10 and the second lower wiring layer 32.

The first via electrode 41 is embedded in the third insulating layer 15 and is exposed from the principal surface of the third insulating layer 15. The second via electrode 42 is embedded in the third insulating layer 15 at an interval in the X direction from the first via electrode 41 and is exposed from the principal surface of the third insulating layer 15. The second via electrode 42 is disposed at the +X side with respect to the first via electrode 41.

An upper end portion of the first via electrode 41 is electrically connected to the first end portion 10a of the resistance layer 10. A lower end portion of the first via electrode 41 is electrically connected to a +X side end portion of the first lower wiring layer 31. An upper end portion of the second via electrode 42 is electrically connected to the second end portion 10b of the resistance layer 10. A lower end portion of the second via electrode 42 is electrically connected to a −X side end portion of the second lower wiring layer 32.

The resistance layer 10 is thereby electrically connected to the first via electrode 41 and the second via electrode 42. Also, the first end portion 10a of the resistance layer 10 is electrically connected to the first lower wiring layer 31 via the first via electrode 41. Also, the second end portion 10b of the resistance layer 10 is electrically connected to the second lower wiring layer 32 via the second via electrode 42. The resistance layer 10 is thereby connected in series to the first lower wiring layer 31 and the second lower wiring layer 32.

In this preferred embodiment, the first via electrode 41 is formed in a circular shape in plan view. The planar shape of the first via electrode 41 is arbitrary. The first via electrode 41 may be formed in a polygonal shape, such as a triangular shape, a quadrilateral shape, or a hexagonal shape, etc., or an elliptical shape in plan view instead of a circular shape. The first via electrode 41 is formed in a convergent shape that narrows in width from the upper end portion toward the lower end portion in sectional view.

The first via electrode 41 has a laminated structure that includes a main body layer 43 and a barrier layer 44. The main body layer 43 is embedded in the third insulating layer 15. The main body layer 43 may contain tungsten (W) or copper (Cu). In this preferred embodiment, the main body layer 43 has a single layer structure constituted of a tungsten layer.

The barrier layer 44 is interposed between the third insulating layer 15 and the main body layer 43. In this preferred embodiment, the barrier layer 44 has a laminated structure in which a plurality of electrode layers are laminated. In this preferred embodiment, the barrier layer 44 includes a Ti layer and a TiN layer that are formed in that order from the third insulating layer 15. The barrier layer 44 may instead have a single layer structure constituted of the Ti layer or the TiN layer.

In this preferred embodiment, the second via electrode 42 is formed in a circular shape in plan view. The planar shape of the second via electrode 42 is arbitrary. The second via electrode 42 may be formed in a polygonal shape, such as a triangular shape, a quadrilateral shape, or a hexagonal shape, etc., or an elliptical shape in plan view instead of a circular shape. The second via electrode 42 is formed in a convergent shape that narrows in width from the upper end portion toward the lower end portion in sectional view.

The second via electrode 42 has a laminated structure that includes a main body layer 45 and a barrier layer 46. The main body layer 45 is embedded in the third insulating layer 15. The main body layer 45 may contain tungsten (W) or copper (Cu). In this preferred embodiment, the main body layer 45 has a single layer structure constituted of a tungsten layer.

The barrier layer 46 is interposed between the third insulating layer 15 and the main body layer 45. In this preferred embodiment, the barrier layer 46 has a laminated structure in which a plurality of electrode layers are laminated. In this preferred embodiment, the barrier layer 46 includes a Ti layer and a TiN layer that are formed in that order from the third insulating layer 15. The barrier layer 46 may instead have a single layer structure constituted of the Ti layer or the TiN layer.

The first upper wiring layer 51 is formed on the fourth insulating layer 16. The first upper wiring layer 51 forms one of top wiring layers of the multilayer wiring structure 12. The first upper wiring layer 51 is electrically connected to the first lower wiring layer 31.

The second upper wiring layer 52 is formed on the fourth insulating layer 16 at an interval in the X direction from the first upper wiring layer 51. In plan view, the first upper wiring layer 51 is disposed at the −X side with respect to the resistance layer 10 and the second upper wiring layer 52 is disposed at the +X side with respect to the resistance layer 10. The second upper wiring layer 52 forms one of the top wiring layers of the multilayer wiring structure 12. The second upper wiring layer 52 is electrically connected to the second lower wiring layer 32.

The resistance layer 10 is thereby electrically connected to the first upper wiring layer 51 via the first lower wiring layer 31. Also, the resistance layer 10 is electrically connected to the second upper wiring layer 52 via the second lower wiring layer 32. The resistance layer 10 is connected in series to the first upper wiring layer 51 and the second upper wiring layer 52 via the first lower wiring layer 31 and the second lower wiring layer 32.

The first upper wiring layer 51 is formed at an interval from the resistance layer 10 in plan view. The first upper wiring layer 51 does not overlap with the resistance layer 10 in plan view. An entirety of the resistance layer 10 is exposed from the first upper wiring layer 51 in plan view.

The second upper wiring layer 52 is formed at an interval from the resistance layer 10 in plan view. The second upper wiring layer 52 does not overlap with the resistance layer 10 in plan view. The entirety of the resistance layer 10 is exposed from the second upper wiring layer 52 in plan view.

That is, the resistance layer 10 is formed in a region between the first upper wiring layer 51 and the second upper wiring layer 52 in plan view. A parasitic capacitance can thereby be suppressed in a region between the resistance layer 10 and the first upper wiring layer 51. Also, a parasitic capacitance can be suppressed in a region between the resistance layer 10 and the second upper wiring layer 52.

In this preferred embodiment, the resistance layer 10 is formed at intervals from the first upper wiring layer 51 and the second upper wiring layer 52 in plan view. The parasitic capacitance can thereby be suppressed appropriately in the region between the resistance layer 10 and the first upper wiring layer 51. Also, the parasitic capacitance can be suppressed appropriately in the region between the resistance layer 10 and the second upper wiring layer 52.

A thickness of the first upper wiring layer 51 and the second upper wiring layer 52 may be not less than 100 nm and not more than 15000 nm. The thickness of the first upper wiring layer 51 and the second upper wiring layer 52 may be not less than 100 nm and not more than 1500 nm, not less than 1500 nm and not more than 3000 nm, not less than 3000 nm and not more than 4500 nm, not less than 4500 nm and not more than 6000 nm, not less than 6000 nm and not more than 7500 nm, not less than 7500 nm and not more than 9000 nm, not less than 9000 nm and not more than 10500 nm, not less than 10500 nm and not more than 12000 nm, not less than 12000 nm and not more than 13500 nm, or not less than 13500 nm and not more than 15000 nm. In this preferred embodiment, the thickness of the first upper wiring layer 51 and the second upper wiring layer 52 is approximately 2200 nm.

In this preferred embodiment, the first upper wiring layer 51 has a laminated structure in which a plurality of electrode layers are laminated. The first upper wiring layer 51 includes a first barrier layer 53, a main body layer 54, and a second barrier layer 55 that are laminated in that order from above the fourth insulating layer 16.

In this preferred embodiment, the first barrier layer 53 has a laminated structure that includes a Ti layer and a TiN layer that are laminated in that order from above the fourth insulating layer 16. The first barrier layer 53 may instead have a single layer structure constituted of the Ti layer or the TiN layer.

The main body layer 54 has a resistance value less than a resistance value of the first barrier layer 53 and a resistance value of the second barrier layer 55. The main body layer 54 has a thickness exceeding a thickness of the first barrier layer 53 and a thickness of the second barrier layer 55. The main body layer 54 may contain at least one type of substance among Al, Cu, AlSiCu alloy, AlSi alloy, and AlCu alloy. In this preferred embodiment, the main body layer 54 has a single layer structure constituted of an AlCu alloy layer.

In this preferred embodiment, the second barrier layer 55 has a laminated structure that includes a Ti layer and a TiN layer that are laminated in that order from above the main body layer 54. The second barrier layer 55 may instead have a single layer structure constituted of the Ti layer or the TiN layer.

In this preferred embodiment, the second upper wiring layer 52 has a laminated structure in which a plurality of electrode layers are laminated. The second upper wiring layer 52 includes a first barrier layer 56, a main body layer 57, and a second barrier layer 58 that are laminated in that order from above the fourth insulating layer 16.

In this preferred embodiment, the first barrier layer 56 has a laminated structure that includes a Ti layer and a TiN layer that are laminated in that order from above the fourth insulating layer 16. The first barrier layer 56 may instead have a single layer structure constituted of the Ti layer or the TiN layer.

The main body layer 57 has a resistance value less than a resistance value of the first barrier layer 56 and a resistance value of the second barrier layer 58. The main body layer 57 has a thickness exceeding a thickness of the first barrier layer 56 and a thickness of the second barrier layer 58. The main body layer 57 may contain at least one type of substance among Al, Cu, AlSiCu alloy, AlSi alloy, and AlCu alloy. In this preferred embodiment, the main body layer 57 has a single layer structure constituted of an AlCu alloy layer.

In this preferred embodiment, the second barrier layer 58 has a laminated structure that includes a Ti layer and a TiN layer that are laminated in that order from above the main body layer 57. The second barrier layer 58 may instead have a single layer structure constituted of the Ti layer or the TiN layer.

The first long via electrode 61 is electrically connected to the first lower wiring layer 31 and the first upper wiring layer 51. The second long via electrode 62 is electrically connected to the second lower wiring layer 32 and the second upper wiring layer 52.

The resistance layer 10 is thereby electrically connected to the first upper wiring layer 51 via the first via electrode 41, the first lower wiring layer 31, and the first long via electrode 61. Also, the resistance layer 10 is electrically connected to the second upper wiring layer 52 via the second via electrode 42, the second lower wiring layer 32, and the second long via electrode 62.

The first long via electrode 61 is formed at a side (the −X side) of the resistance layer 10. In this preferred embodiment, the first long via electrode 61 is positioned on a straight line connecting the first via electrode 41 and the second via electrode 42.

The second long via electrode 62 is formed at a side (the +X side) of the resistance layer 10 at an interval in the X direction from the first long via electrode 61. In this preferred embodiment, the second long via electrode 62 opposes the first long via electrode 61 with the resistance layer 10 interposed therebetween. The second long via electrode 62 is positioned on the straight line connecting the first via electrode 41 and the second via electrode 42.

The resistance layer 10 is thereby positioned on a straight line connecting the first long via electrode 61 and the second long via electrode 62. The resistance layer 10 is positioned on a straight line connecting the first via electrode 41, the second via electrode 42, the first long via electrode 61, and the second long via electrode 62. In this preferred embodiment, the resistance layer 10 extends along the straight line connecting the first long via electrode 61 and the second long via electrode 62.

In this preferred embodiment, the first long via electrode 61 is formed in a circular shape in plan view. The planar shape of the first long via electrode 61 is arbitrary. The first long via electrode 61 may be formed in a polygonal shape, such as a triangular shape, a quadrilateral shape, or a hexagonal shape, etc., or an elliptical shape in plan view instead of a circular shape.

The first long via electrode 61 penetrates through the third insulating layer 15 and the fourth insulating layer 16, is embedded in the third insulating layer 15 and the fourth insulating layer 16, and is exposed from the principal surface of the fourth insulating layer 16.

An upper end portion of the first long via electrode 61 is electrically connected to a +X direction end portion of the first upper wiring layer 51. A lower end portion of the first long via electrode 61 is electrically connected to a −X direction end portion of the first lower wiring layer 31. The first long via electrode 61 is formed in a convergent shape that narrows in width from the upper end portion toward the lower end portion in sectional view.

The first long via electrode 61 has a laminated structure that includes a main body layer 63 and a barrier layer 64. The main body layer 63 is embedded in the third insulating layer 15 and the fourth insulating layer 16. The main body layer 63 may contain tungsten (W) or copper (Cu). In this preferred embodiment, the main body layer 63 has a single layer structure constituted of a tungsten layer.

The barrier layer 64 is interposed between the main body layer 63 and the third insulating layer 15 and between the main body layer 63 and the fourth insulating layer 16. In this preferred embodiment, the barrier layer 64 has a laminated structure in which a plurality of electrode layers are laminated. In this preferred embodiment, the barrier layer 64 includes a Ti layer and a TiN layer that are formed in that order from the third insulating layer 15. The barrier layer 64 may instead have a single layer structure constituted of the Ti layer or the TiN layer.

In this preferred embodiment, the second long via electrode 62 is formed in a circular shape in plan view. The planar shape of the second long via electrode 62 is arbitrary. The second long via electrode 62 may be formed in a polygonal shape, such as a triangular shape, a quadrilateral shape, or a hexagonal shape, etc., or an elliptical shape in plan view instead of a circular shape.

The second long via electrode 62 penetrates through the third insulating layer 15 and the fourth insulating layer 16, is embedded in the third insulating layer 15 and the fourth insulating layer 16, and is exposed from the principal surface of the fourth insulating layer 16.

An upper end portion of the second long via electrode 62 is electrically connected to a −X side end portion of the second upper wiring layer 52. A lower end portion of the second long via electrode 62 is electrically connected to a +X side end portion of the second lower wiring layer 32. The second long via electrode 62 is formed in a convergent shape that narrows in width from the upper end portion toward the lower end portion in sectional view.

The second long via electrode 62 has a laminated structure that includes a main body layer 65 and a barrier layer 66. The main body layer 65 is embedded in the third insulating layer 15 and the fourth insulating layer 16. The main body layer 65 may contain tungsten (W) or copper (Cu). In this preferred embodiment, the main body layer 65 has a single layer structure constituted of a tungsten layer.

The barrier layer 66 is interposed between the main body layer 65 and the third insulating layer 15 and between the main body layer 65 and the fourth insulating layer 16. In this preferred embodiment, the barrier layer 66 has a laminated structure in which a plurality of electrode layers are laminated. In this preferred embodiment, the barrier layer 66 includes a Ti layer and a TiN layer that are formed in that order from the third insulating layer 15. The barrier layer 66 may instead have a single layer structure constituted of the Ti layer or the TiN layer.

Referring to FIG. 2, the connection circuit forming layer 21 includes a wiring 71 electrically connecting the functional device and the resistance layer 10. The wiring 71 is formed selectively inside the first insulating layer 13 and the second insulating layer 14 and is routed from the device region 6 to the outside region 7.

More specifically, the wiring 71 includes one or a plurality of connection wiring layers 72 electrically connected to the functional device in the device region 6. The one or plurality connection wiring layers 72 are formed on either or both of the first insulating layer 13 and the second insulating layer 14. In FIG. 2, an example where two connection wiring layers 72 are formed on the first insulating layer 13 is shown.

The one or plurality of connection wiring layers 72 are selectively routed from the device region 6 to the outside region 7. Each connection wiring layer 72 has the same laminated structure as the first lower wiring layer 31 (second lower wiring layer 32) and the first upper wiring layer 51 (second upper wiring layer 52). A specific description of the connection wiring layers 72 shall be omitted.

The wiring 71 includes one or a plurality of connection via electrodes 73. The one or plurality of connection via electrodes 73 connect the one or plurality of connection wiring layers 72 to any first lower wiring layer 31 (second lower wiring layer 32) or any first upper wiring layer 51 (second upper wiring layer 52).

The one or plurality of connection via electrodes 73 are formed on either or both of the first insulating layer 13 and the second insulating layer 14. In FIG. 2, an example where one connection wiring layer 72 is connected to the first lower wiring layer 31 by two connection via electrodes 73 is shown.

Each connection via electrode 73 has the same laminated structure as the first via electrode 41 (second via electrode 42) and the first long via electrode 61 (second long via electrode 62). A specific description of the connection via electrodes 73 shall be omitted.

Referring to FIG. 2, a top insulating layer 81 is formed on the multilayer wiring structure 12. The top insulating layer 81 selectively covers the first upper wiring layer 51 and the second upper wiring layer 52. The top insulating layer 81 covers a connection portion of the first upper wiring layer 51 and the first long via electrode 61 in plan view. The top insulating layer 81 covers a connection portion of the second upper wiring layer 52 and the second long via electrode 62 in plan view.

In the outside region 7, a first pad opening 82 and a second pad opening 83 are formed in the top insulating layer 81. The first pad opening 82 exposes a partial region of the first upper wiring layer 51 as a first pad region 84. More specifically, the first pad opening 82 exposes, as the first pad region 84, a region of the first upper wiring layer 51 besides the connection portion of the first upper wiring layer 51 and the first long via electrode 61.

The second pad opening 83 exposes a partial region of the second upper wiring layer 52 as a second pad region 85. More specifically, the second pad opening 83 exposes, as the second pad region 85, a region of the second upper wiring layer 52 besides the connection portion of the second upper wiring layer 52 and the second long via electrode 62.

In this preferred embodiment, the top insulating layer 81 has a laminated structure that includes a passivation layer 86 and a resin layer 87. In FIG. 1, the resin layer 87 is shown with hatching for clarity. In the resin layer 87, an opening 88 for laser trimming for forming the notched portion 110 in the resistance layer 10 is formed in a region between the first upper wiring layer 51 and the second upper wiring layer 52 in plan view. The opening 88 is formed at a position directly above a region of the resistance layer 10 that includes the connection portion 10c and a peripheral portion thereof.

The passivation layer 86 may have a laminated structure that includes a silicon oxide film and a silicon nitride film. In this case, the silicon nitride film may be formed on the silicon oxide film or the silicon oxide film may be formed on the silicon nitride film.

The passivation layer 86 may have a single layer structure constituted of a silicon oxide film or a silicon nitride film. The passivation layer 86 is preferably formed of an insulating material that differs in type of substance from the multilayer wiring structure 12. In this preferred embodiment, the passivation layer 86 has a single layer structure constituted of a silicon nitride film.

The resin layer 87 may contain a photosensitive resin. The photosensitive resin may be of a positive type or a negative type. In this preferred embodiment, the resin layer 87 contains a polyimide as an example of a negative type photosensitive resin. The resin layer 87 may contain a polybenzoxazole as an example of a positive type photosensitive resin instead.

At times in the following, a direction (in this example, the Y direction) in which the notched portion 110 of the resistance layer 10 extends shall be referred to as a first direction and a direction (in this example, the X direction) that is a direction along a principal surface of the resistance layer 10 and is a direction orthogonal to the first direction shall be referred to as a second direction. As shown in FIG. 2, FIG. 3, and FIG. 5, an uneven structure 121 is formed in a region (hereinafter referred to as an unevenness forming region 120) of the first principal surface 3 of the semiconductor layer 2 that includes at least a region directly below the resistance layer 10. In this preferred embodiment, the unevenness forming region 120 is set to the region of the first principal surface 3 of the semiconductor layer 2 directly below the resistance layer 10.

The uneven structure 121 includes a plurality of grooves 122 that extend in parallel to the first direction (Y direction) at equal intervals in the second direction (X direction) and projection portions 123 that are portions between adjacent grooves 122.

A width L of the grooves 122 is preferably not less than 0.2 nm and not more than 1 μm. An interval (width of the projection portions 123) S of the grooves 122 is preferably not less than 0.2 nm and not more than 1 μm. The width L of the grooves 122 and the interval S of the grooves 122 are preferably equal. That is, preferably the width L of the grooves 122 and the interval S of the grooves 122 are the same and the width L of the grooves 122 and the interval S of the grooves 122 are preferably not less than 0.2 nm and not more than 1 μm. In this preferred embodiment, the width L of the grooves 122 and the interval S of the grooves 122 are 0.5 μm.

A depth of the grooves 122 is preferably not less than 100 nm and not more than 300 nm and more preferably not less than 150 nm and not more than 300 nm. In this preferred embodiment, the depth of the grooves 122 is 250 nm.

Here, a region wider than the region of the first principal surface 3 of the semiconductor layer 2 directly below the resistance layer 10 may be set as the unevenness forming region 120. For example, a region that includes the region of the first principal surface 3 of the semiconductor layer 2 directly below the resistance layer 10 and a region in its vicinity may be set as the unevenness forming region 120. Also, a region of the first principal surface 3 of the semiconductor layer 2 belonging to the outside region 7 may be set as the unevenness forming region 120.

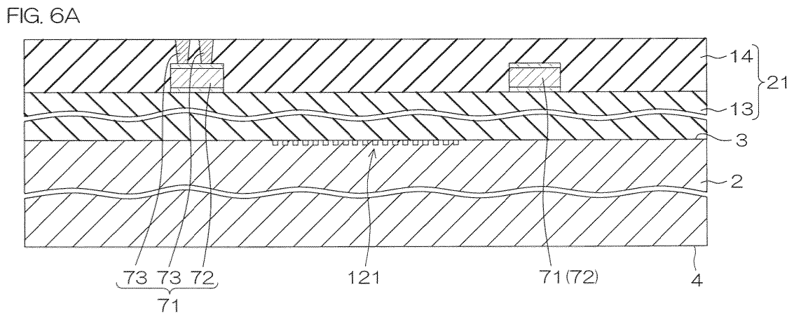

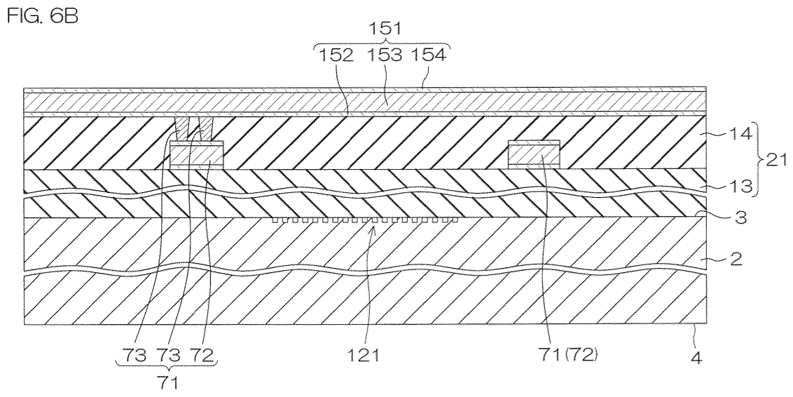

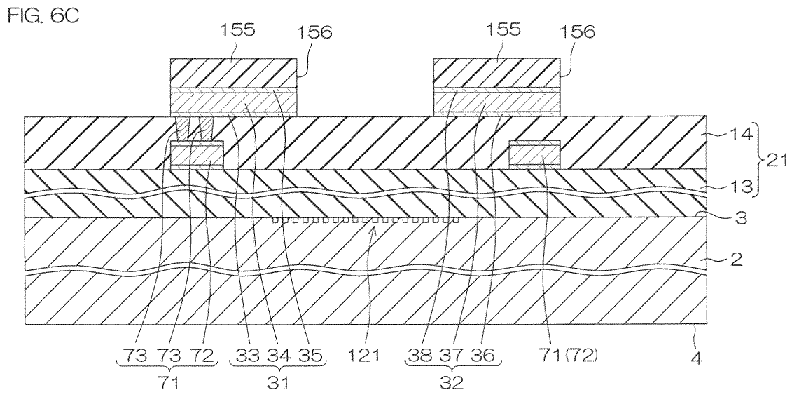

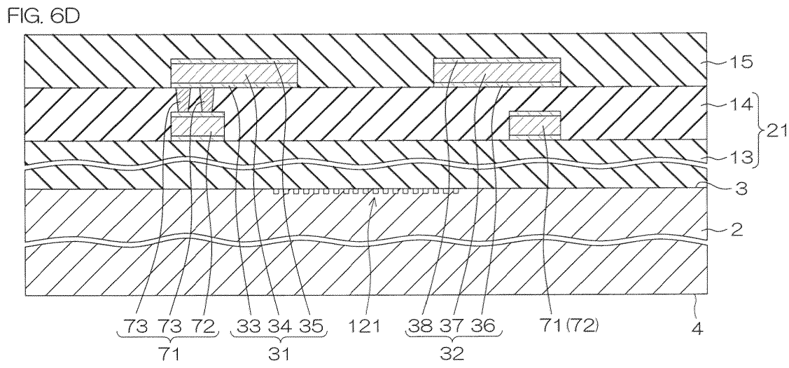

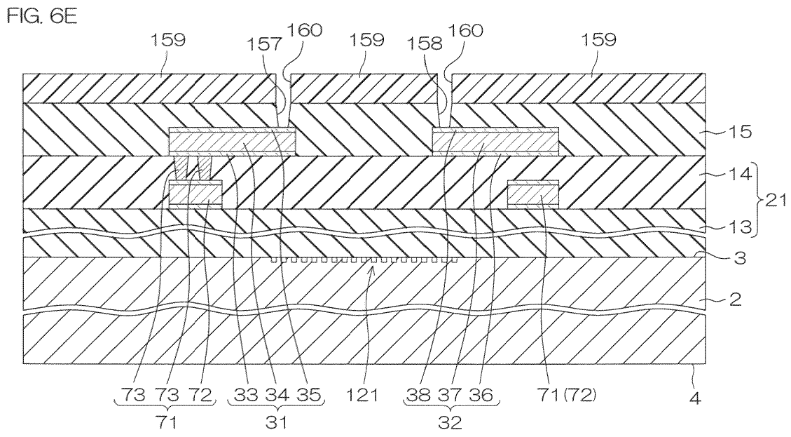

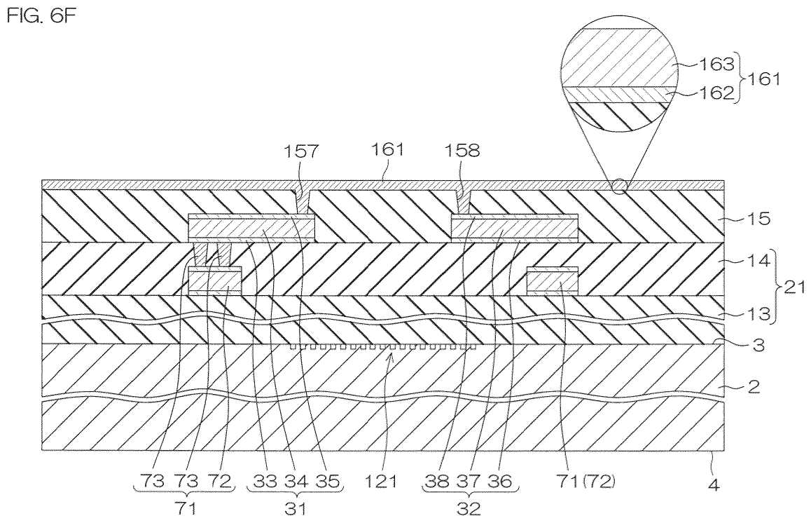

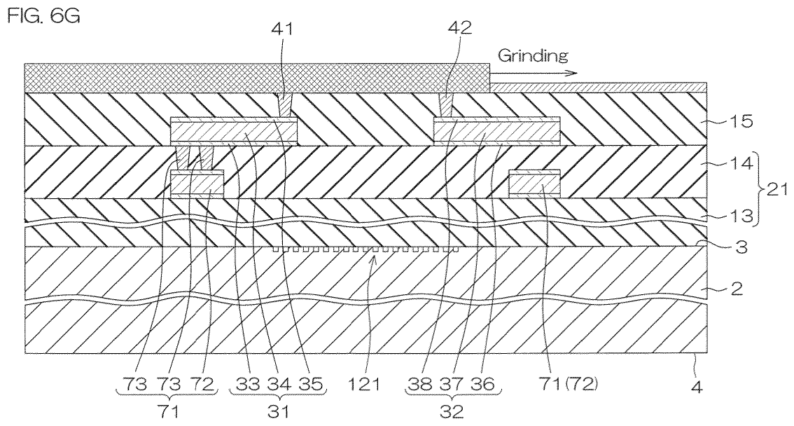

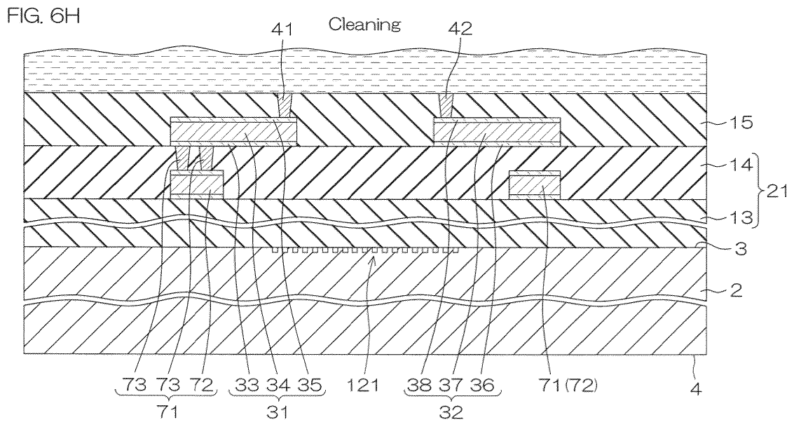

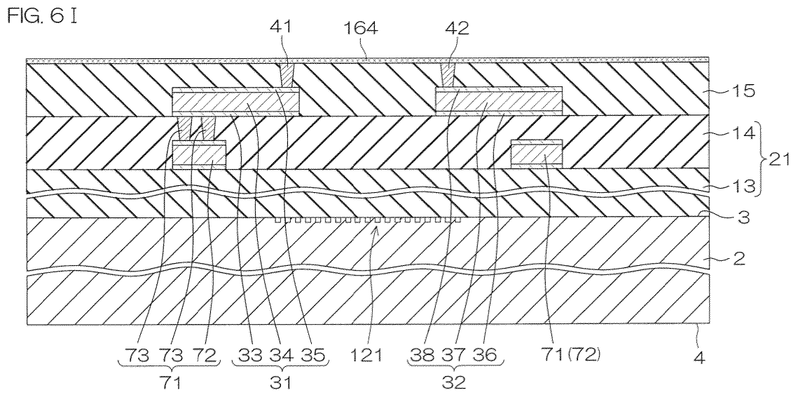

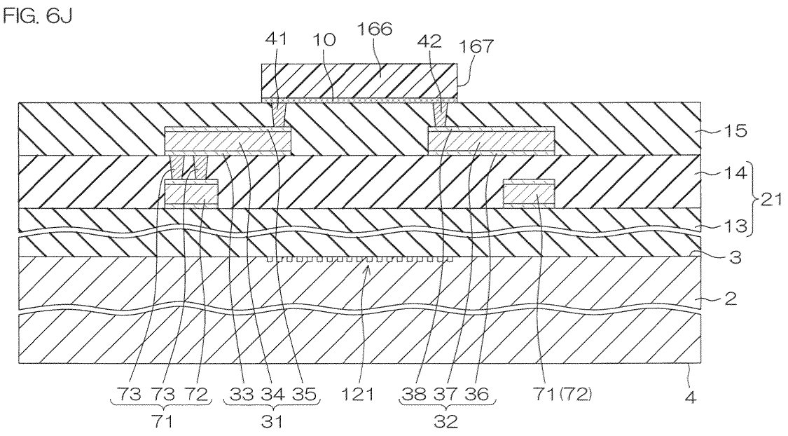

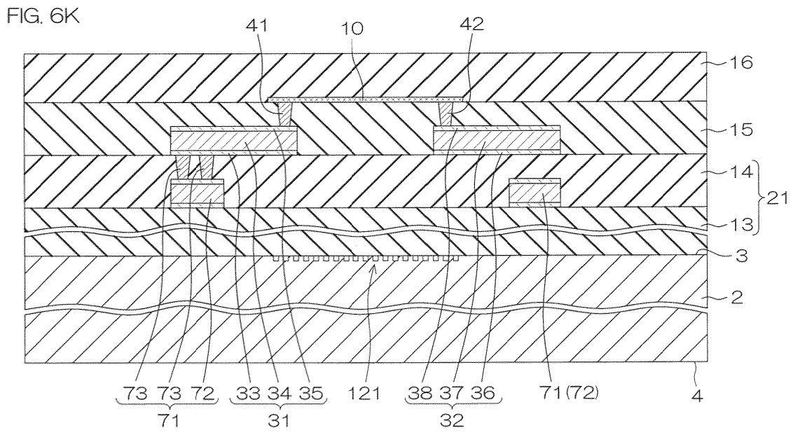

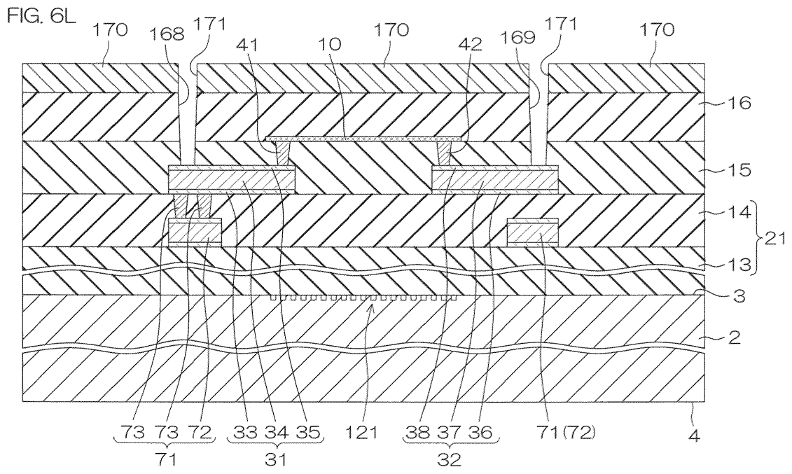

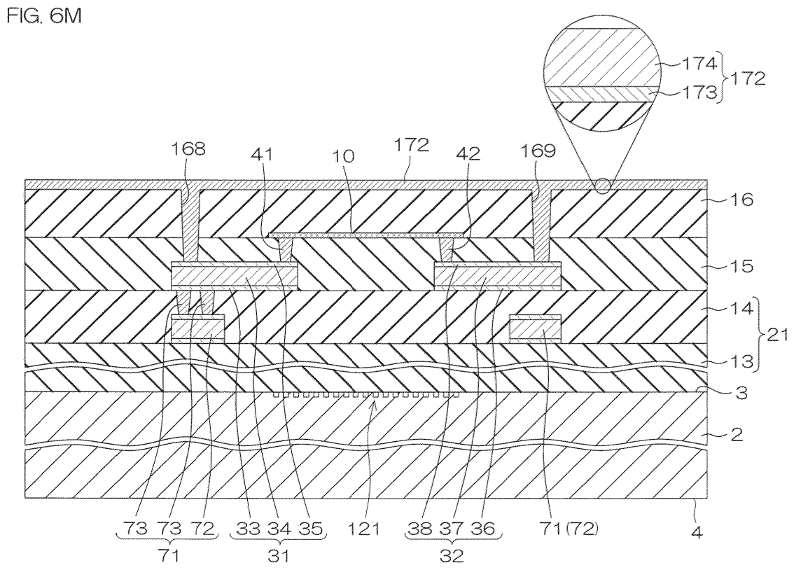

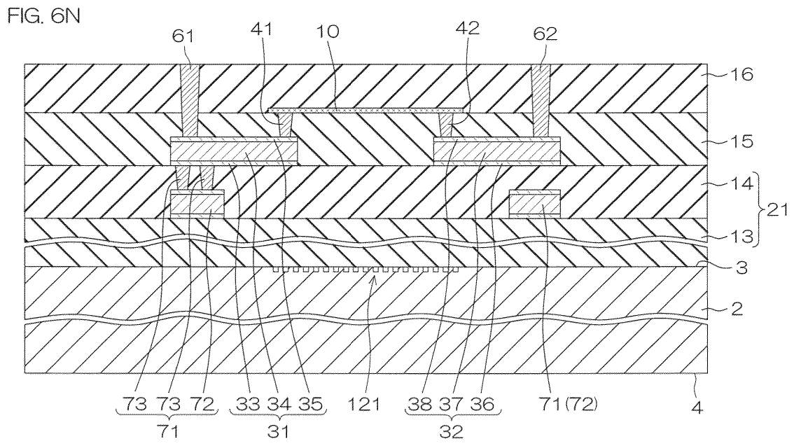

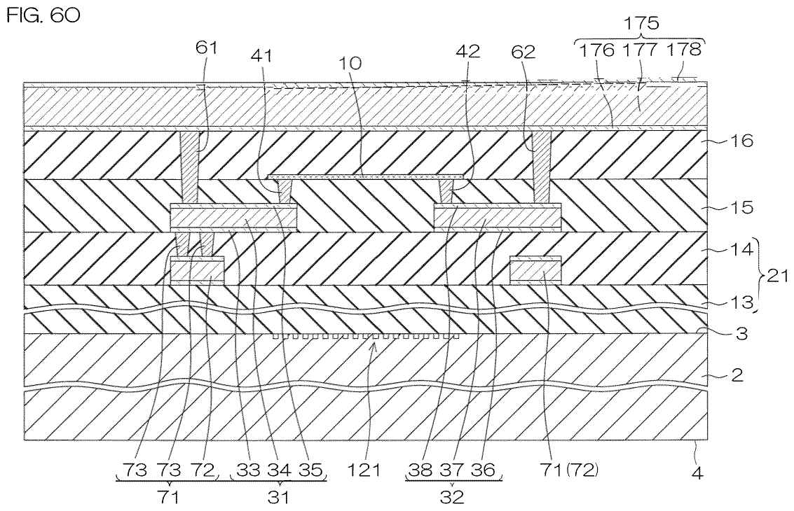

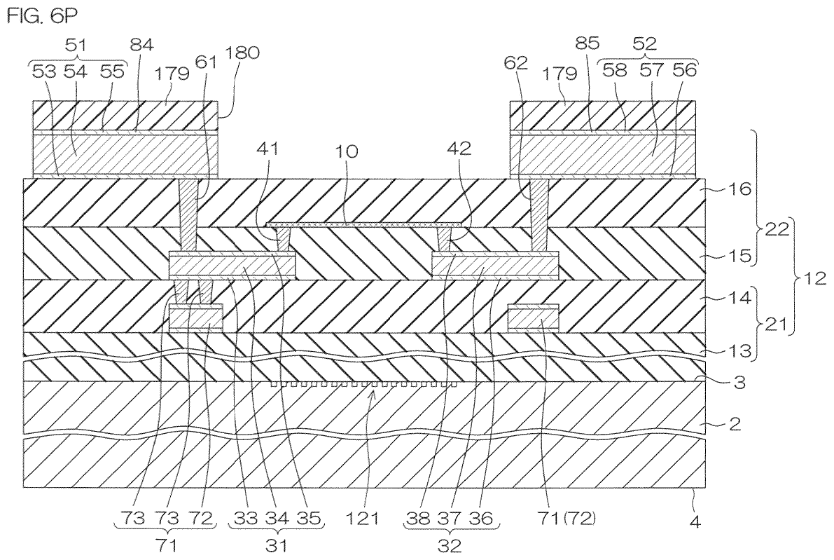

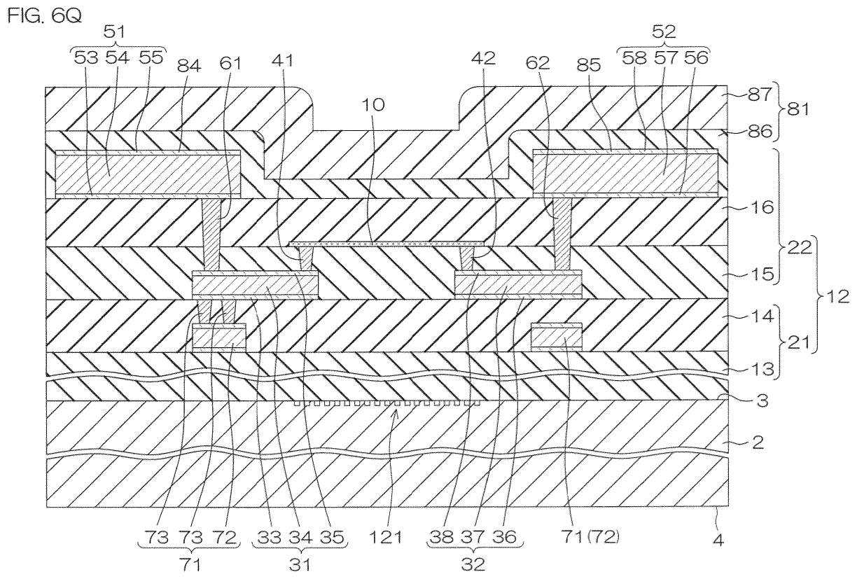

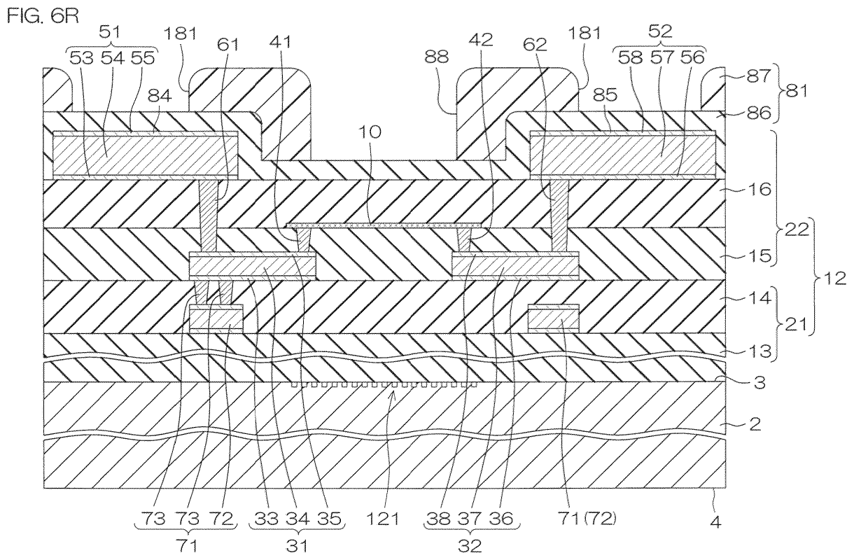

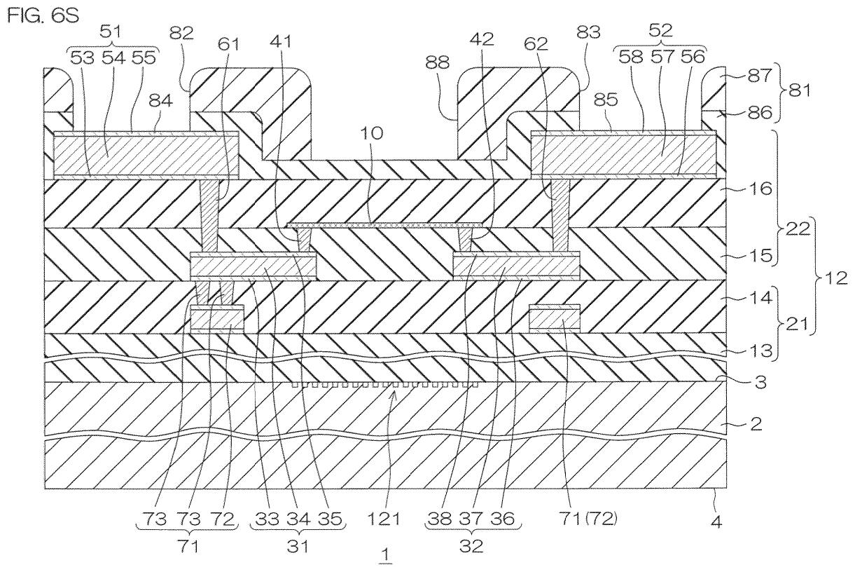

FIG. 6A to FIG. 6S are sectional views for describing an example of a method for manufacturing the electronic component 1 shown in FIG. 1. FIG. 6A to FIG. 6S are sectional views of a portion corresponding to FIG. 2.

A silicon wafer (not shown) is prepared as a base substrate of the semiconductor substrate 2. A plurality of component forming regions corresponding to a plurality of the electronic components 1 are arrayed and set in a matrix on a front surface of the silicon wafer. Boundary regions (scribe lines) are provided between neighboring component forming regions. The boundary regions are regions of band shape having a substantially fixed width, extend in two orthogonal directions, and are formed in a lattice. The plurality of electronic components 1 are obtained by cutting apart the silicon wafer along the boundary regions after performing necessary processes on the silicon wafer.

Referring to FIG. 6A, in manufacturing the electronic component 1, first, the semiconductor layer (silicon wafer) 2 in which the device region 6 and the outside region 7 are formed is prepared. Next, the uneven structure 121 is formed in the unevenness forming region 120 that includes a region of the first principal surface 3 of the semiconductor layer 2 to be directly below the resistance layer 10.

In this step, first a mask (not shown) having a predetermined pattern is formed on the first principal surface 3 of the semiconductor layer 2. The mask has a plurality of openings exposing regions of the first principal surface 3 of the semiconductor layer 2 in which the plurality of grooves 122 are to be formed.

Next, unnecessary portions of the semiconductor layer 2 are removed by etching via the mask. The plurality of grooves 122 are thereby formed in the unevenness forming region 120 of the first principal surface 3 of the semiconductor layer 2. The uneven structure 121 including the plurality of grooves 122 that extend in parallel in the first direction (Y direction) and the projection portions 123 that are the portions between adjacent grooves 122 is thereby formed in the unevenness forming region 120. The mask is thereafter removed.

Next, the connection circuit forming layer 21 of the multilayer wiring structure 12 is formed on the first principal surface 3 of the semiconductor layer 2. The connection circuit forming layer 21 includes the first insulating layer 13, the second insulating layer 14, the one or plurality of connection wiring layers 72, and the one or plurality of connection via electrodes 73. The first insulating layer 13 and the second insulating layer 14 are flattened by a CMP (chemical mechanical polishing) method using a polishing agent (abrasive grains). A detailed description of a step of forming the connection circuit forming layer 21 shall be omitted.

Next, referring to FIG. 6B, a first base wiring layer 151 that is to be a base of the first lower wiring layer 31 and the second lower wiring layer 32 is formed on the connection circuit forming layer 21. The step of forming the first base wiring layer 151 includes steps of forming a first barrier layer 152, a main body layer 153, and a second barrier layer 154 in that order on the connection circuit forming layer 21.

The step of forming the first barrier layer 152 includes steps of forming a Ti layer and a TiN layer in that order on the connection circuit forming layer 21. The Ti layer and the TiN layer may be formed respectively by a sputtering method. The step of forming the main body layer 153 includes a step of forming an AlCu alloy layer on the first barrier layer 152. The AlCu alloy layer may be formed by a sputtering method.

The step of forming the second barrier layer 154 includes steps of forming a Ti layer and a TiN layer in that order on the main body layer 153. The Ti layer and the TiN layer may be formed respectively by a sputtering method.

Next, referring to FIG. 6C, a mask 155 having a predetermined pattern is formed on the first base wiring layer 151. The mask 155 covers regions of the first base wiring layer 151 in which the first lower wiring layer 31 and the second lower wiring layer 32 are to be formed and has an opening 156 that exposes other regions.

Next, unnecessary portions of the first base wiring layer 151 are removed by an etching method via the mask 155. The first base wiring layer 151 is thereby divided into the first lower wiring layer 31 and the second lower wiring layer 32. The mask 155 is thereafter removed.

Next, referring to FIG. 6D, the third insulating layer 15 that covers the first lower wiring layer 31 and the second lower wiring layer 32 is formed on the connection circuit forming layer 21. The third insulating layer 15 may be formed by a CVD (chemical vapor deposition) method.

Next, referring to FIG. 6E, a first via hole 157 that exposes the first lower wiring layer 31 and a second via hole 158 that exposes the second lower wiring layer 32 are formed in the third insulating layer 15.

In this step, first, a mask 159 having a predetermined pattern is formed on the third insulating layer 15. The mask 159 has a plurality of openings 160 that expose regions of the third insulating layer 15 in which the first via hole 157 and the second via hole 158 are to be formed.

Next, unnecessary portions of the third insulating layer 15 are removed by an etching method via the mask 159. The first via hole 157 and the second via hole 158 are thereby formed in the third insulating layer 15. The mask 159 is thereafter removed.

Next, referring to FIG. 6F, a base electrode layer 161 that is to be a base of the first via electrode 41 and the second via electrode 42 is formed on the third insulating layer 15. The step of forming the base electrode layer 161 includes steps of forming a barrier layer 162 and a main body layer 163 in that order on the third insulating layer 15.

The step of forming the barrier layer 162 includes steps of forming a Ti layer and a TiN layer in that order on the third insulating layer 15. The Ti layer and the TiN layer may be formed respectively by a sputtering method. The step of forming the main body layer 163 includes a step of forming a tungsten layer on the barrier layer 162. The tungsten layer may be formed by a CVD method.

Next, referring to FIG. 6G, a step of removing the base electrode layer 161 is performed. The base electrode layer 161 is removed until the third insulating layer 15 is exposed. The step of removing the base electrode layer 161 may include a step of removing the base electrode layer 161 by grinding.

In this preferred embodiment, the step of grinding the base electrode layer 161 is performed by a CMP (chemical mechanical polishing) method using a polishing agent (abrasive grains). The step of grinding the base electrode layer 161 may include a step of flattening the principal surface of the third insulating layer 15. The first via electrode 41 is thereby formed inside the first via hole 157. Also, the second via electrode 42 is formed inside the second via hole 158.

Next, referring to FIG. 6H, the polishing agent (abrasive grains) attached to the principal surface of the third insulating layer 15 is removed by cleaning using a chemical liquid. In this step, a portion of the third insulating layer 15 is removed together with the polishing agent (abrasive grains) by the chemical liquid.

Next, referring to FIG. 6I, a base resistance layer 164 that is to be a base of the resistance layer 10 is formed on the principal surface of the third insulating layer 15. The base resistance layer 164 contains CrSi. The base resistance layer 164 may be formed by a sputtering method.

Next, the base resistance layer 164 (CrSi) is crystallized. The step of crystallizing the base resistance layer 164 includes a step of performing annealing at a temperature and for a time at and until which the base resistance layer 164 (CrSi) crystallizes. The base resistance layer 164 may be heated at a temperature of not less than 400° and not more than 600° for not less than 60 minutes and not more than 120 minutes.

Next, referring to FIG. 6J, a mask 166 having a predetermined pattern is formed on the base resistance layer 164. The mask 166 covers a region of the base resistance layer 164 in which the resistance layer 10 is to be formed and has an opening 167 that exposes other regions.

Next, unnecessary portions of the base resistance layer 164 are removed by an etching method via the mask 166. The resistance layer 10 is thereby formed. The mask 166 is thereafter removed.

Next, referring to FIG. 6K, the fourth insulating layer 16 that covers the resistance layer 10 is formed on the third insulating layer 15. The fourth insulating layer 16 may be formed by a CVD method.

Next, referring to FIG. 6L, a first via hole 168 that exposes the first lower wiring layer 31 and a second via hole 169 that exposes the second lower wiring layer 32 are formed in the third insulating layer 15 and the fourth insulating layer 16.

In this step, first, a mask 170 having a predetermined pattern is formed on the fourth insulating layer 16. The mask 170 has a plurality of openings 171 that expose regions of the fourth insulating layer 16 in which the first via hole 168 and the second via hole 169 are to be formed.

Next, unnecessary portions of the third insulating layer 15 and the fourth insulating layer 16 are removed by an etching method via the mask 170. The first via hole 168 and the second via hole 169 are thereby formed in the third insulating layer 15 and the fourth insulating layer 16. The mask 170 is thereafter removed.

Next, referring to FIG. 6M, a base electrode layer 172 that is to be a base of the first long via electrode 61 and the second long via electrode 62 is formed on the fourth insulating layer 16. The step of forming the base electrode layer 172 includes steps of forming a barrier layer 173 and a main body layer 174 in that order on the fourth insulating layer 16.

The step of forming the barrier layer 173 includes steps of forming a Ti layer and a TiN layer in that order on the fourth insulating layer 16. The Ti layer and the TiN layer may be formed respectively by a sputtering method. The step of forming the main body layer 174 includes a step of forming a tungsten layer on the barrier layer 173. The tungsten layer may be formed by a CVD method.

Next, referring to FIG. 6N, a step of removing the base electrode layer 172 is performed. The base electrode layer 172 is removed until the fourth insulating layer 16 is exposed. The step of removing the base electrode layer 172 may include a step of removing the base electrode layer 172 by grinding.

In this preferred embodiment, the step of grinding the base electrode layer 172 is performed by a CMP method using a polishing agent (abrasive grains). The step of grinding the base electrode layer 172 may include a step of flattening the principal surface of the fourth insulating layer 16. The first long via electrode 61 and the second long via electrode 62 are thereby formed inside the first via hole 168 and inside the second via hole 169, respectively.

After the step of grinding the base electrode layer 172, the polishing agent (abrasive grains) attached to the principal surface of the fourth insulating layer 16 may be removed by cleaning using a chemical liquid. A portion of the fourth insulating layer 16 may be removed together with the polishing agent (abrasive grains) by the chemical liquid.

Next, referring to FIG. 6O, a second base wiring layer 175 that is to be a base of the first upper wiring layer 51 and the second upper wiring layer 52 is formed on the fourth insulating layer 16. The step of forming the second base wiring layer 175 includes steps of forming a first barrier layer 176, a main body layer 177, and a second barrier layer 178 in that order on the fourth insulating layer 16.

The step of forming the first barrier layer 176 includes steps of forming a Ti layer and a TiN layer in that order on the fourth insulating layer 16. The Ti layer and the TiN layer may be formed respectively by a sputtering method. The step of forming the main body layer 177 includes a step of forming an AlCu alloy layer on the first barrier layer 176. The AlCu alloy layer may be formed by a sputtering method.

The step of forming the second barrier layer 178 includes steps of forming a Ti layer and a TiN layer in that order on the main body layer 177. The Ti layer and the TiN layer may be formed respectively by a sputtering method.

Next, referring to FIG. 6P, a mask 179 having a predetermined pattern is formed on the second base wiring layer 175. The mask 179 covers regions of the second base wiring layer 175 in the outside region 7 in which the first upper wiring layer 51 and the second upper wiring layer 52 are to be formed and has an opening 180 that exposes other regions.

Next, unnecessary portions of the second base wiring layer 175 are removed by an etching method via the mask 179. The second base wiring layer 175 is thereby divided into the first upper wiring layer 51 and the second upper wiring layer 52. Also, the multilayer wiring structure 12 that includes the connection circuit forming layer 21 and the resistance circuit forming layer 22 is thereby formed on the first principal surface 3 of the semiconductor layer 2. The mask 179 is thereafter removed.

Next, referring to FIG. 6O, the passivation layer 86 is formed on the multilayer wiring structure 12. The passivation layer 86 contains silicon nitride. The passivation layer 86 may be formed by a CVD method.

Next, the resin layer 87 is coated on the passivation layer 86. The resin layer 87 may contain a polyimide as an example of a negative type photosensitive resin.

Next, referring to FIG. 6R, the resin layer 87 is selectively exposed and thereafter developed. An opening 88 for laser trimming and a plurality of openings 181 that are to be bases of the first pad opening 82 and the second pad opening 83 are thereby formed in the resin layer 87.

Next, referring to FIG. 6S, unnecessary portions of the passivation layer 86 are removed by an etching method via the resin layer 87. The first pad opening 82 and the second pad opening 83 that expose the first upper wiring layer 51 and the second upper wiring layer 52 respectively are thereby formed.

Thereafter, the notched portion 110 is formed in the resistance layer 10 by laser trimming. In this step, a laser light is irradiated toward the resistance layer 10 from the opening 88 in the resin layer 87. The laser light is then scanned in the first direction (Y direction) to make a notch in the resistance layer 10. And when the resistance value becomes a target resistance value, the trimming is stopped. The electronic component 1 is manufactured through steps including the above.

An electronic component that is substantially the same in arrangement as the preferred embodiment but is such that, in the outside region 7 in which the resistance circuit 11, the uneven structure 121 is not formed in a predetermined region (the unevenness forming region 120) of the first principal surface 3 of the semiconductor layer 2 that includes a region directly below the resistance layer 10 shall be deemed to be a reference example. In the reference example, the first principal surface of the semiconductor layer 2 is formed flatly across its entirety in the outside region 7 in which the resistance circuit 11 is formed.

With the reference example, during laser trimming, an incident laser light and a reflected light reflected from the first principal surface 3 of the semiconductor layer 2 undergo interference. Thereby, locations at which an electric field strength is high and locations at which the electric field strength is low appear alternately in the thickness direction inside the multilayer wiring structure 12. Height positions at which the electric field strength becomes high and height positions at which the electric field strength becomes low are determined by a wavelength of the laser light and material properties (refractive indices) of members constituting the multilayer wiring structure 12.

To form the notched portion 110 in the resistance layer 10, the resistance layer 10 must be disposed at a thickness direction position inside the multilayer wiring structure 12 at which the electric field strength becomes high. However, within a wafer surface, variation is present in a film thickness of an insulating layer (lower insulating layer) between the semiconductor layer 2 and the resistance layer 10 and therefore, variation is present in a distance between the resistance layer 10 and the semiconductor layer 2 among respective component forming regions. Thereby, among the plurality of component forming regions on the wafer surface, there occurs that with which the resistance layer 10 is disposed at a position at which the electric field strength becomes low and the notched portion 110 cannot be formed in the resistance layer 10.

With the preferred embodiment, the uneven structure 121 is formed in the unevenness forming region 120 that includes the region of the first principal surface 3 of the semiconductor layer 2 directly below the resistance layer 10. The uneven structure 121 includes the plurality of grooves 122 that extend in parallel to the first direction (Y direction) at equal intervals in the second direction (X direction) and the projection portions 123 that are portions between two adjacent grooves 122. The levels of the electric field strength inside the multilayer wiring structure 12 during laser trimming are thereby dispersed and therefore, a proportion of electronic components with which the appropriate notched portion 110 cannot be formed can be reduced with respect to all electronic components cut out from a single wafer.

The following experiment was performed to confirm effects of the preferred embodiment.

First, a plurality of samples, corresponding to a plurality of types of resistance components being of substantially the same structure as the structure shown in FIG. 2 but differing in an uneven structure in the unevenness forming region 120, were prepared. However, as the resistance layer 10, that with which an X direction length and a Y direction length are 50 μm was used. Also, the region of the first principal surface 3 of the semiconductor layer 2 directly below the resistance layer 10 was set to an unevenness forming region 120A.

Samples corresponding to a certain single type of resistance component were prepared by preparing a wafer having a plurality of component forming regions and preparing the resistance component of that type in the respective component forming regions. Specifically, the first to thirteenth samples described below were prepared.

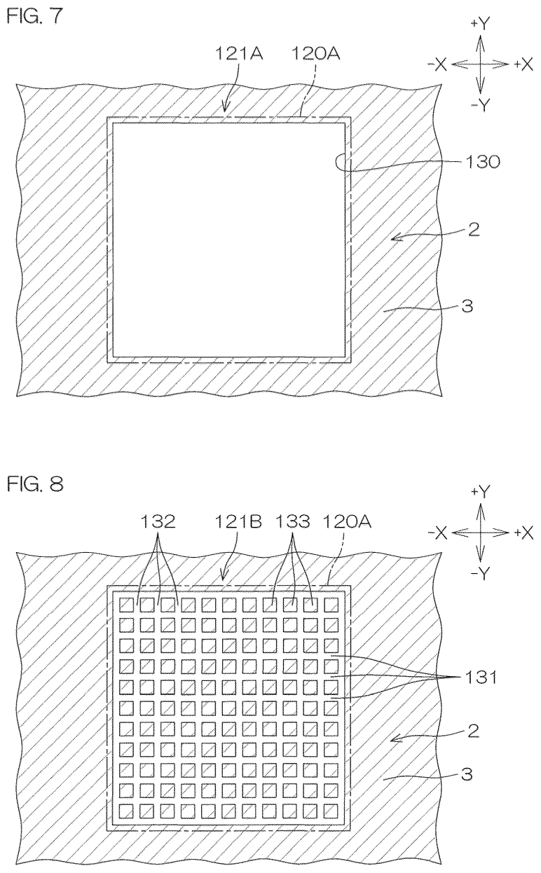

First sample: As shown in FIG. 7, an uneven structure 121A is constituted of a single recess 130 formed in the unevenness forming region 120A. An area of a planar shape of the recess 130 is substantially equal to an area of a planar shape of the unevenness forming region 120A. A depth of the recess 130 is 250 nm.

Second to seventh samples: As shown in FIG. 8, an uneven structure 121B has a plurality of first grooves 131 extending in parallel in the X direction at equal intervals in the Y direction, a plurality of second grooves 132 extending in parallel in the Y direction at equal intervals in the X direction, and a plurality of projection portions 133 of square shape in plan view surrounded by the first grooves 131 and the second grooves 132. An interval of two adjacent first grooves 131 and an interval of two adjacent second grooves 132 are equal. A depth of the first grooves 131 and the second grooves 132 is 250 nm. Differences of the second to seventh samples are as follows.

Second sample: In plan view, a length of one side of each projection portion 133 is 1 μm and a proportion of a total area of upper surfaces of the projection portions 133 with respect to an entirety of the unevenness forming region 120A is 75%.

Third sample: In plan view, the length of one side of each projection portion 133 is 1 μm and the proportion of the total area of upper surfaces of the projection portions 133 with respect to the entirety of the unevenness forming region 120A is 50%.

Fourth sample: In plan view, the length of one side of each projection portion 133 is 1 μm and the proportion of the total area of upper surfaces of the projection portions 133 with respect to the entirety of the unevenness forming region 120A is 25%.

Fifth sample: In plan view, the length of one side of each projection portion 133 is 0.5 μm and the proportion of the total area of upper surfaces of the projection portions 133 with respect to the entirety of the unevenness forming region 120A is 50%.

Sixth sample: In plan view, the length of one side of each projection portion 133 is 0.5 μm and the proportion of the total area of upper surfaces of the projection portions 133 with respect to the entirety of the unevenness forming region 120A is 25%.

Seventh sample: In plan view, the length of one side of each projection portion 133 is 0.35 μm and the proportion of the total area of upper surfaces of the projection portions 133 with respect to the entirety of the unevenness forming region 120A is 37%.

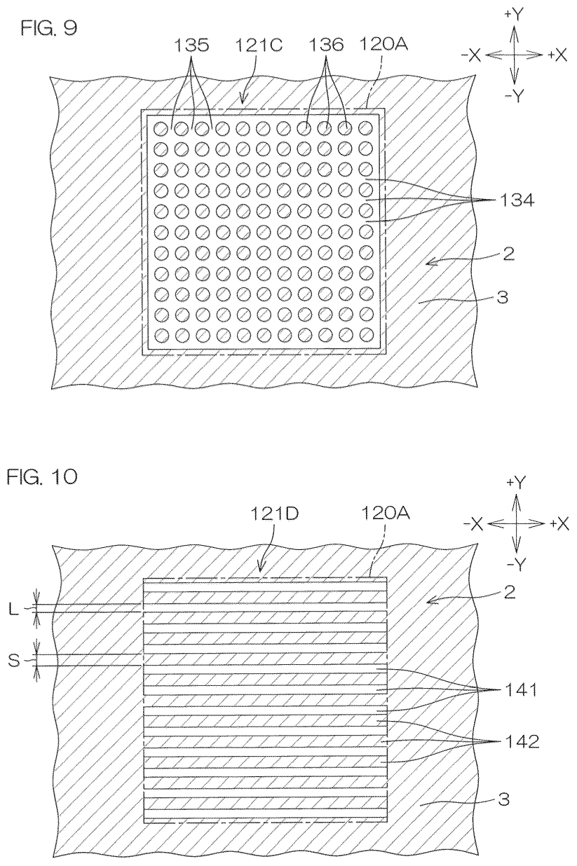

Eighth and ninth samples: As shown in FIG. 9, an uneven structure 121C has a plurality of first grooves 134 extending in parallel in the X direction at equal intervals in the Y direction, a plurality of second grooves 135 extending in parallel in the Y direction at equal intervals in the X direction, and a plurality of projection portions 136 of circular shape in plan view surrounded by the first grooves 134 and the second grooves 135. An interval of two adjacent first grooves 134 and an interval of two adjacent second grooves 135 are equal. The plurality of projection portions 136 are disposed at equal intervals in the X direction and the Y direction. A depth of the first grooves 134 and the second grooves 135 is 250 nm. Differences of the eighth and ninth samples are as follows.

Eighth sample: In plan view, a diameter of the projection portions 136 is 1 μm and an interval of two projection portions 136 adjacent in the X direction (interval of two projection portions 136 adjacent in the Y direction) is 0.5 μm.

Ninth sample: In plan view, the diameter of the projection portions 136 is 1 μm and the interval of two projection portions 136 adjacent in the X direction (interval of two projection portions 136 adjacent in the Y direction) is 0.26 μm.

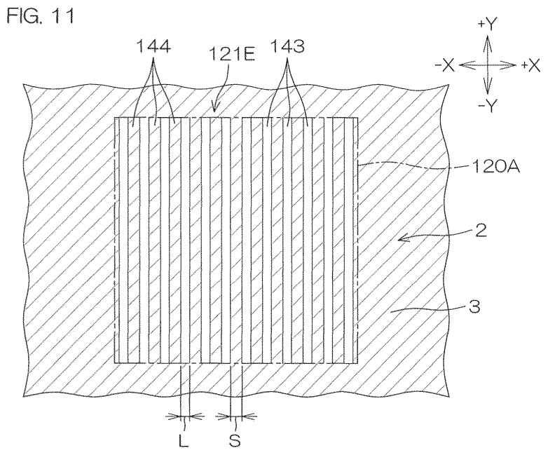

Tenth and eleventh samples: As shown in FIG. 10, an uneven structure 121D is constituted of a plurality of grooves 141 extending in parallel in the second direction (X direction) at equal intervals in the first direction (Y direction) and projection portions 142 that are portions between two adjacent grooves 141. A depth of the grooves 141 is 250 nm. Differences of the tenth and eleventh samples are as follows.

Tenth sample: A width L of the grooves 141 and an interval (width of the projection portions 142) S of the grooves 141 are 1 μm.

Eleventh sample: The width L of the grooves 141 and the interval (width of the projection portions 142) S of the grooves 141 are 0.5 μm.

Twelfth and thirteen samples: As shown in FIG. 11 and as with the uneven structure 121 of the preferred embodiment, an uneven structure 121E is constituted of a plurality of grooves 143 extending in parallel in the first direction (Y direction) at equal intervals in the second direction (X direction) and projection portions 144 that are portions between two adjacent grooves 143. A depth of the grooves 143 is 250 nm. Differences of the twelfth and thirteenth samples are as follows.

Twelfth sample: A width L of the grooves 143 and an interval (width of the projection portions 144) S of the grooves 143 are 1 μm.

Thirteenth sample: The width L of the grooves 143 and the interval (width of the projection portions 144) S of the grooves 143 are 0.5 μm.

With each of the plurality of resistance components selected in advance in each sample, a laser light was irradiated perpendicularly onto a length central portion in the second direction (X direction) of the principal surface of the resistance layer 10 and the laser light was scanned in the first direction (Y direction). It was then determined whether or not it was possible to cut the resistance layer 10 according to whether or not the resistance value changed. A wavelength of the laser light is 1064 nm.

With each of the first, twelfth, and thirteenth samples, whether or not it was possible to cut the resistance layer 10 was examined with twenty resistance components selected in advance.

With each of the second to eleventh samples, whether or not it was possible to cut the resistance layer 10 was examined with six resistance components selected in advance.

The respective determination results were as follows.

First sample: With all twenty components, the resistance layer 10 could not be cut (20 failures/20).

Second sample: With three of six components, the resistance layer 10 could not be cut (3 failures/6).

Third to seventh sample: With six of six components, the resistance layer 10 could not be cut (6 failures/6).

Eighth sample: With five of six components, the resistance layer 10 could not be cut (5 failures/6).

Ninth sample: With six of six components, the resistance layer 10 could not be cut (6 failures/6).

Tenth sample: With five of six components, the resistance layer 10 could not be cut (5 failures/6).

Eleventh sample: With six of six components, the resistance layer 10 could not be cut (6 failures/6).

Twelfth sample: With eleven of twenty components, the resistance layer 10 could not be cut (11 failures/20).

Thirteenth sample: With one of twenty components, the resistance layer 10 could not be cut (1 failure/20).

From the above results, it can be understood that the twelfth and thirteenth samples were lower than the other first to eleventh samples in a proportion of resistance components with which the resistance layer 10 cannot be cut with respect to the number of components subject to examination.

That is, it can be understood that, if a cutting direction with respect to the resistance layer 10 is the first direction (Y direction) and a direction that is a direction along the principal surface of the resistance layer 10 and is a direction orthogonal to the first direction is the second direction (X direction), the proportion of resistance components with which the resistance layer 10 cannot be cut can be reduced by forming the plurality of grooves 141 extending in the first direction (Y direction) at intervals in the second direction (X direction) in the unevenness forming region 120.

Also, it can be understood that the proportion of resistance components with which the resistance layer 10 cannot be cut can be reduced further when the width L and the interval S of the grooves 141 are set to 0.5 μm than when set to 1 μm. That is, according to the preferred embodiment, the proportion of electronic components with which the appropriate notched portion 110 cannot be formed can be reduced with respect to all electronic components cut out from a single wafer.

While a preferred embodiment of the present disclosure was described in detail above, this is merely a specific example used to clarify the technical contents of the present disclosure and the present disclosure should not be interpreted as being limited to this specific example and the scope of the present disclosure is limited only by the appended claims.

What is claimed is:

1. An electronic component comprising:
a semiconductor layer that has a first principal surface and a second principal surface at an opposite thereto;
a lower insulating layer that is formed on the first principal surface of the semiconductor layer;
a resistance layer that is formed on the lower insulating layer and has a notched portion extending in a predetermined first direction from a portion of a peripheral edge thereof;
an upper insulating layer that is formed on the lower insulating layer such as to cover the resistance layer; and
an uneven structure that is formed in a predetermined region of the first principal surface of the semiconductor layer including at least a region directly below the resistance layer; and
wherein the uneven structure includes a plurality of grooves disposed at equal intervals in a second direction that is a direction along the first principal surface and is orthogonal to the first direction and extend in parallel to the first direction and a projection portion that is a portion between two adjacent grooves.

2. The electronic component according to claim 1, wherein the resistance layer, in plan view, is of a quadrilateral shape that has first opposing sides constituted of two sides parallel to the second direction and second opposing sides constituted of two sides parallel to the first direction and the notched portion extends from a length intermediate portion of one side among the first opposing sides toward the other side among the first opposing sides.

3. The electronic component according to claim 2, comprising: a first via electrode that is embedded in the lower insulating layer and with which an upper end is connected to a portion of the resistance layer close to one side among the second opposing sides; and
a second via electrode that is embedded in the lower insulating layer and with which an upper end is connected to a portion of the resistance layer close to the other side among the second opposing sides.

4. The electronic component according to claim 3, comprising: a first lower wiring layer that is formed in a region at the lower insulating layer side with respect to the resistance layer and is electrically connected to the first via electrode; and
a second lower wiring layer that is formed in a region at the lower insulating layer side with respect to the resistance layer and is electrically connected to the second via electrode.

5. The electronic component according to claim 4, wherein the first lower wiring layer extends outward from an inner side of the resistance layer with respect to the one side among the second opposing sides in plan view,
the second lower wiring layer extends outward from the inner side of the resistance layer with respect to the other side among the second opposing sides in plan view, and
the first lower wiring layer and the second lower wiring layer are disposed at an interval in the second direction in plan view.

6. The electronic component according to claim 5, wherein the resistance layer is connected in series to the first lower wiring layer and the second lower wiring layer.

7. The electronic component according to claim 6, comprising: a first upper wiring layer that is formed on the upper insulating layer and is electrically connected to the first lower wiring layer; and
a second upper wiring layer that is formed on the upper insulating layer and is electrically connected to the second lower wiring layer.

8. The electronic component according to claim 7, wherein the resistance layer is connected in series to the first upper wiring layer and the second upper wiring layer.

9. The electronic component according to claim 8, comprising: a first long via electrode that penetrates through the upper insulating layer and a portion of the lower insulating layer and is electrically connected to the first lower wiring layer and the first upper wiring layer; and
a second long via electrode that penetrates through the upper insulating layer and a portion of the lower insulating layer and is electrically connected to the second lower wiring layer and the second upper wiring layer.

10. The electronic component according to claim 9, wherein the resistance layer is positioned on a straight line joining the first long via electrode and the second long via electrode in plan view.

11. The electronic component according to claim 1, wherein the semiconductor layer includes a device region in which a functional device is formed and an outside region outside the device region and
the resistance layer is formed in the outside region in plan view.

12. The electronic component according to claim 1, wherein the resistance layer is constituted of a metal thin film containing at least one among CrSi, CrSio, and CrSiN.

13. The electronic component according to claim 1, wherein a depth of the grooves is not less than 100 nm and not more than 300 nm and
a width of the grooves and an interval of the grooves are not less than 0.2 μm and not more than 1 μm.

14. The electronic component according to claim 1, wherein the depth of the grooves is not less than 150 nm and not more than 300 nm and
the width of the grooves and the interval of the grooves are not less than 0.2 μm and not more than 1 μm.

15. The electronic component according to claim 1, wherein the lower insulating layer includes a plurality of lower silicon oxide films that are laminated and
the upper insulating layer includes an upper silicon oxide film that is formed on the lower insulating layer such as to cover the resistance layer.

16. A method for manufacturing an electronic component comprising:
a step of forming an uneven structure in a predetermined region of a first principal surface of a semiconductor layer having the first principal surface and a second principal surface at an opposite thereto;
a step of forming a lower insulating layer on the first principal surface of the semiconductor layer;
a step of forming a resistance layer on the lower insulating layer;
a step of forming an upper insulating layer on the lower insulating layer such as to cover the resistance layer; and
a step of forming, in the resistance layer, a notched portion extending in a predetermined first direction from a portion of a peripheral edge of the resistance layer by irradiating a laser light onto the resistance layer via the upper insulating layer; and
wherein the predetermined region is a region that includes at least a region of the first principal surface of the semiconductor layer directly below the resistance layer and,
in the step of forming the uneven structure, the uneven structure is formed by forming, in the predetermined region, a plurality of grooves extending in parallel to the first direction at equal intervals in a second direction that is a direction along the first principal surface and is orthogonal to the first direction.
